(19) United States
(12) Patent Application Publication
(10) Pub. No.: US 2024/0234555 A1
(43) Pub. Date: Jul. 11, 2024

(54) SEMICONDUCTOR DEVICE AND MANUFACTURING METHOD

(71) Applicant: FUJI ELECTRIC CO., LTD., Kanagawa (JP)

(72) Inventor: Koh YOSHIKAWA, Matsumoto-city (JP)

(21) Appl. No.: 18/611,728

(22) Filed: Mar. 21, 2024

Related U.S. Application Data
(63) Continuation of application No. PCT/JP2023/014827, filed on Apr. 12, 2023.

(30) Foreign Application Priority Data
Apr. 13, 2022 (JP) 2022-066313

(51) Int. Cl. H01L 29/739; H01L 29/861

(52) U.S. Cl. CPC H01L 29/7397; H01L 29/861

(57) ABSTRACT

Provided is a semiconductor device including: a semiconductor substrate which has an upper surface and a lower surface and is provided with a drift region of a first conductivity type; a transistor portion which includes a collector region of a second conductivity type in contact with the lower surface of the semiconductor substrate and an emitter region of the first conductivity type provided in contact with the upper surface of the semiconductor substrate and having a doping concentration higher than that of the drift region; and a diode portion which includes a cathode region of the first conductivity type in contact with the lower surface of the semiconductor substrate, and an avalanche breakdown voltage in the diode portion is 0.7 times or more and less than 1 time an avalanche breakdown voltage in the transistor portion.

The contents of the following patent application(s) are incorporated herein by reference:
NO. 2022-066313 filed in JP on Apr. 13, 2022
NO. PCT/JP2023/014827 filed in WO on Apr. 12, 2023

### BACKGROUND

### 1. Technical Field

The present invention relates to a semiconductor device and a manufacturing method.

### 2. Related Art

Conventionally, a reverse-conducting IGBT (RC-IGBT) in which a transistor portion such as an insulated gate bipolar transistor (IGBT) and a diode portion are provided on a single semiconductor substrate is known (see, for example, Patent Documents 1 and 2).

### CITATION LIST

### Patent Document

Patent Document 1: Japanese Patent Application Publication No. 2018-78230

Patent Document 2: Japanese Patent Application Publication No. 2015-135954

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3 illustrates a view showing an example of a cross section e-e in FIG. 2.

FIG. 4 is an example of current density-voltage characteristics of a transistor portion 70 and a diode portion 80 according to a reference example.

FIG. 5 is an example of current density-voltage characteristics of the transistor portion 70 and the diode portion 80 according to the embodiment.

FIG. 6 illustrates an example of a cross section e-e according to the embodiment.

FIG. 7 illustrates another example of the cross section e-e according to the embodiment.

FIG. 8 illustrates another example of the cross section e-e according to the embodiment.

FIG. 9 illustrates another example of the cross section e-e according to the embodiment.

FIG. 10 illustrates another example of the cross section e-e according to the embodiment.

FIG. 11 illustrates another example of the cross section e-e according to the embodiment.

FIG. 12 illustrates another example of the cross section e-e according to the embodiment.

FIG. 13 illustrates another example of the cross section e-e according to the embodiment.

FIG. 14 illustrates another example of the cross section e-e according to the embodiment.

FIG. 15 illustrates another example of the cross section e-e according to the embodiment.

FIG. 16 illustrates another example of the cross section e-e according to the embodiment.

FIG. 17 illustrates another example of the cross section e-e according to the embodiment.

FIG. 18 illustrates a relationship between a trench interval in the transistor portion 70 and the diode portion 80 and an avalanche breakdown voltage in the transistor portion 70 and the diode portion 80.

FIG. 19 illustrates a relationship between a trench length in the transistor portion 70 and the diode portion 80 and the avalanche breakdown voltage in the transistor portion 70 and the diode portion 80.

FIG. 20 illustrates the relationship between a trench interval in the transistor portion 70 and the diode portion 80 and the avalanche breakdown voltage in the transistor portion 70 and the diode portion 80.

FIG. 21 illustrates a relationship between a dose amount (or doping concentration) in a second lower end region 204 in the diode portion 80 and the avalanche breakdown voltage in the diode portion 80.

FIG. 22 illustrates a non-destructive maximum energy density of the semiconductor device 100.

FIG. 23 illustrates a relationship between an avalanche breakdown voltage Va_d in the diode portion 80 and the non-destructive maximum energy density.

FIG. 24 illustrates an example of a manufacturing method of the semiconductor device 100.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. In the present specification, the VOH defect may be referred to as a hydrogen donor. The hydrogen donor may be a donor obtained by the combination of at least a vacancy (V) and hydrogen (H).

In the semiconductor substrate of the present specification, bulk donors of the N type are distributed throughout. The bulk donor is a dopant donor substantially uniformly contained in an ingot during the manufacture of the ingot from which the semiconductor substrate is made. The bulk donor of this example is an element other than hydrogen. The bulk donor dopant is, for example, phosphorous, antimony, arsenic, selenium, or sulfur, but is not limited thereto. The bulk donor of this example is phosphorous. The bulk donor is also contained in a region of the P type. The semiconductor substrate may be a wafer cut out from a semiconductor ingot, or may be a chip obtained by singulating the wafer. The semiconductor ingot may be manufactured by any of a Czochralski method (CZ method), a magnetic-field applied Czochralski method (MCZ method), and a float zone method (FZ method). The ingot of this example is manufactured by the MCZ method.

The concentration of oxygen contained in the substrate manufactured by the MCZ method is 1×10¹⁷ to 7×10¹⁷/cm³. The concentration of oxygen contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. In addition, as the semiconductor substrate, a non-doped substrate not containing a dopant such as phosphorous may be used. In that case, the bulk donor concentration (D0) of the non-doped substrate is, for example, from 1×10¹⁰/cm³ or more and to 5×10¹²/cm³ or less. The bulk donor concentration (D0) of the non-doped substrate is preferably 1×10¹¹/cm³ or more. The bulk donor concentration (D0) of the non-doped substrate is preferably 5×10¹²/cm³ or less. Each concentration in the present invention may be a value at room temperature. As the value at room temperature, a value at 300 K (Kelvin) (about 26.9° C.) may be used as an example.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type. In the specification, a unit system is the SI base unit system unless otherwise particularly noted. Although a unit of length is represented using cm, it may be converted to meters (m) before calculations.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

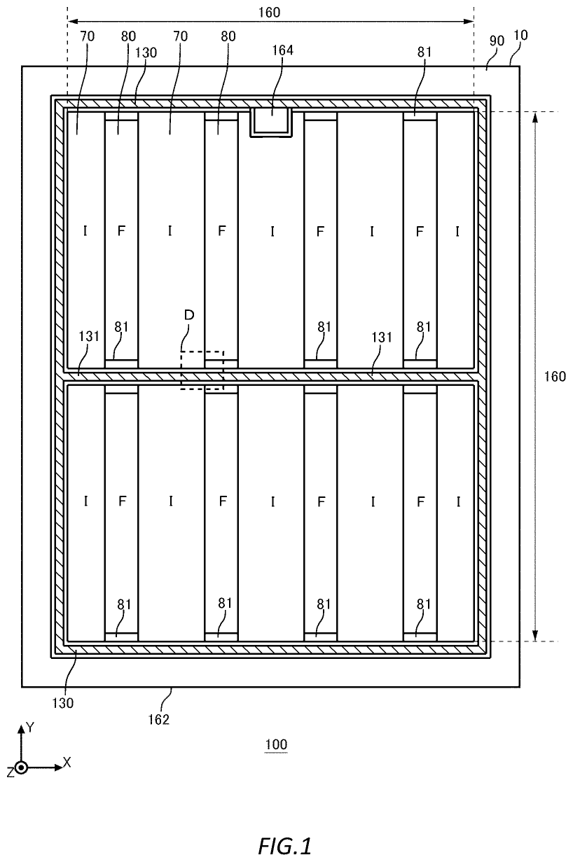

FIG. 1 illustrates a top view showing one example of the semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. In addition, a region sandwiched by the active portion 160 in the top view may also be included in the active portion 160.

The active portion 160 is provided with a transistor portion 70 including a transistor element such as an insulated gate bipolar transistor (IGBT). The active portion 160 may further be provided with a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10. The semiconductor device 100 of this example is a reverse-conducting IGBT (RC-IGBT).

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described later may be the same.

Each of the diode portions 80 includes a cathode region of N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of P+ type may be provided in a region other than the cathode region. In the specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example has an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 of this example encloses the active portion 160 in the top view. A region enclosed by the outer circumferential gate runner 130 in the top view may be the active portion 160. In addition, a well region is formed below the gate runner. The well region is the P type region having a higher concentration than the base region described below, and is formed to a position deeper than the base region from the upper surface of the semiconductor substrate 10. A region enclosed by the well region in the top view may be the active portion 160.

The outer circumferential gate runner 130 is connected to the gate pad 164. The outer circumferential gate runner 130 is arranged above the semiconductor substrate 10. The outer circumferential gate runner 130 may be a metal wiring including aluminum.

The active-side gate runner 131 is provided in the active portion 160. Providing the active-side gate runner 131 in the active portion 160 can reduce a variation in wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 of this example is provided extending in the X axis direction so as to cross the active portion 160 from one side of the outer circumferential gate runner 130 to the other side of the outer circumferential gate runner 130 substantially at the center of the Y axis direction, the outer circumferential gate runner 130 sandwiching the active portion 160. When the active portion 160 is divided by the active-side gate runner 131, the transistor portion 70 and the diode portion 80 may be alternately arranged in the X axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided to enclose the active portion 160.

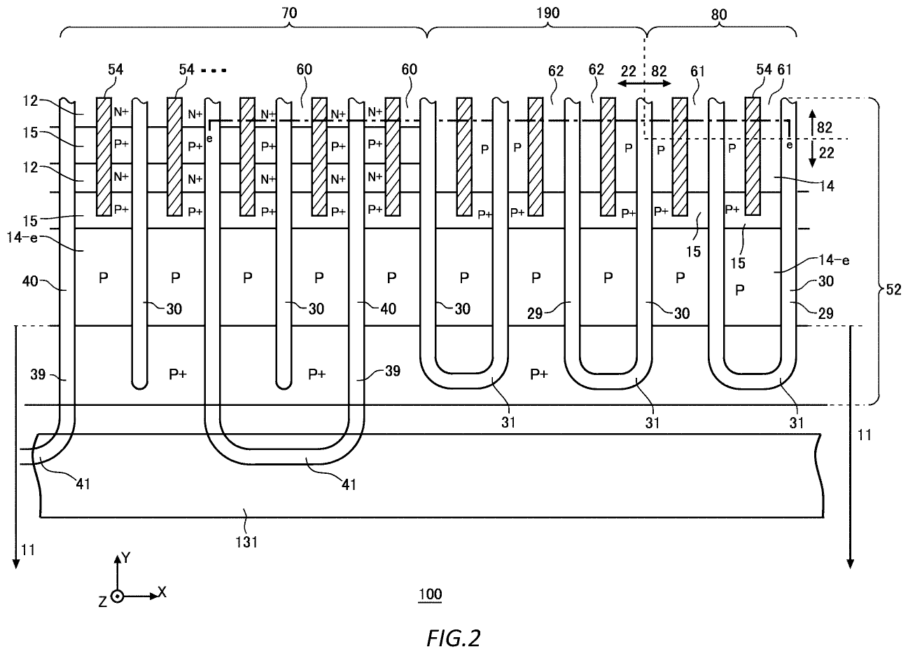

FIG. 2 illustrates an enlarged view of a region D in FIG. 1. The region D is a region including the transistor portion 70, the diode portion 80, and the active-side gate runner 131. The semiconductor device 100 of this example includes a connection region 190 between the transistor portion 70 and the diode portion 80. The semiconductor device 100 of this example includes a gate trench portion 40, a dummy trench portion 30, a well region 11, an emitter region 12, a base region 14, and a contact region 15 which are provided inside the upper surface side of the semiconductor substrate 10. The gate trench portion 40 and the dummy trench portion 30 each are an example of the trench portion. Further, the semiconductor device 100 of this example includes an emitter electrode 52 and the active-side gate runner 131 that are provided above the upper surface of the semiconductor substrate 10. The emitter electrode 52 and the active-side gate runner 131 are provided in isolation each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole 54 is provided passing through the interlayer dielectric film. In FIG. 2, each contact hole 54 is hatched with the diagonal lines.

The emitter electrode 52 is provided on the upper side of the gate trench portion 40, the dummy trench portion 30, the well region 11, the emitter region 12, the base region 14, and the contact region 15. The emitter electrode 52 is in contact with the emitter region 12, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 may not be connected to the emitter electrode 52 and the gate conductive portion, and may be controlled to have a potential different from the potential of the emitter electrode 52 and the potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 of this example is provided away from an end of the contact hole 54 in the Y axis direction toward the active-side gate runner 131 side. The well region 11 is a second conductivity type region in which the doping concentration is higher than the base region 14. The well region 11 may be formed from the upper surface of the semiconductor substrate 10 to a depth deeper than the lower end of the trench portion. The base region 14 of this example is a P type, and the well region 11 is a P+ type.

Each of the transistor portion 70, the connection region 190, and the diode portion 80 includes a plurality of trench portions arranged in the array direction. In the transistor portion 70 of this example, one or more gate trench portions 40 and one or more dummy trench portions 30 are alternately provided along the array direction. In the connection region 190 of this example, a plurality of dummy trench portions 30 are provided along the array direction. In the diode portion 80 of this example, the plurality of dummy trench portions 30 are provided along the array direction. Although the gate trench portion 40 is not provided in the connection region 190 and the diode portion 80 of this example, the gate trench portion 40 may be provided in the connection region 190 and the diode portion 80.

The gate trench portion 40 of this example may include two linear portions 39 extending along the extending direction perpendicular to the array direction (portions of a trench portion that are linear along the extending direction), and the edge portion 41 connecting the two linear portions 39. The extending direction in FIG. 2 is the Y axis direction.

At least a part of the edge portion 41 is desirably provided in a curved shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided or a plurality of dummy trench portions 30 may be provided. The dummy trench portion 30 may have a linear shape extending in the extending direction, or may include linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom in the depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (the Y axis direction) along the trench, on the upper surface of the semiconductor substrate 10. In this example, the transistor portion 70 is provided with a mesa portion 60, the diode portion 80 is provided with a mesa portion 61, and the connection region 190 is provided with a mesa portion 62. As merely referred to as the mesa portion in the specification, it indicates each of the mesa portion 60, the mesa portion 61, and the mesa portion 62.

Each mesa portion is provided with the base region 14. In the mesa portion, a region arranged closest to the active-side gate runner 131, in the base region 14 exposed on the upper surface of the semiconductor substrate 10, is defined as a base region 14-e. While FIG. 2 shows the base region 14-e arranged at one end portion of each mesa portion in the extending direction, the base region 14-e is also arranged at the other end portion of each mesa portion. Each mesa portion may be provided with at least one of an emitter region 12 of a first conductivity type or a contact region 15 of a second conductivity type in a region sandwiched between the base regions 14-e in the top view. The emitter region 12 of this example is an N+ type, and the contact region 15 is a P+ type. The emitter region 12 and the contact region 15 may be provided between the base region 14 and the upper surface of the semiconductor substrate 10 in the depth direction.

The mesa portion 60 of the transistor portion 70 includes the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to the other trench portion in the X axis direction. As an example, the contact region 15 and the emitter region 12 in the mesa portion 60 are alternately arranged along the extending direction of the trench portion (the Y axis direction).

In another example, the contact region 15 and the emitter region 12 in the mesa portion 60 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The emitter region 12 is not provided in the mesa portion 61 of the diode portion 80 and the mesa portion 62 of the connection region 190. The base region 14 and the contact region 15 may be provided on the upper surfaces of the mesa portion 61 and the mesa portion 62. In the region sandwiched between the base regions 14-e on the upper surfaces of the mesa portion 61 and the mesa portion 62, the contact region 15 may be provided in contact with each base region 14-e. The base region 14 may be provided in a region sandwiched between the contact regions 15 on the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 of this example is provided above respective regions of the contact region 15, the base region 14, and the emitter region 12. The contact hole 54 is not provided in regions corresponding to the base region 14-e and the well region 11. The contact hole 54 may be arranged at the center of the mesa portion 60 in the array direction (the X axis direction).

In the diode portion 80, a cathode region 82 of the N+ type is provided in a region in direct contact with the lower surface of the semiconductor substrate 10. On the lower surface of the semiconductor substrate 10, a collector region of the P+ type 22 may be provided in a region where the cathode region 82 is not provided. In the connection region 190, a region adjacent to the lower surface of the semiconductor substrate 10 may be provided with the cathode region 82, may be provided with the collector region 22, or may be provided with both of the cathode region 82 and the collector region 22. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged separately from the well region 11 in the Y axis direction. With this configuration, the distance between the P type region (the well region 11) having a relatively high doping concentration and formed up to the deep position, and the cathode region 82 is ensured, so that the breakdown voltage can be improved. The end portion in the Y axis direction of the cathode region 82 of this example is arranged farther away from the well region 11 than the end portion in the Y axis direction of the contact hole 54. In another example, the end portion in the Y axis direction of the cathode region 82 may be arranged between the well region 11 and the contact hole 54.

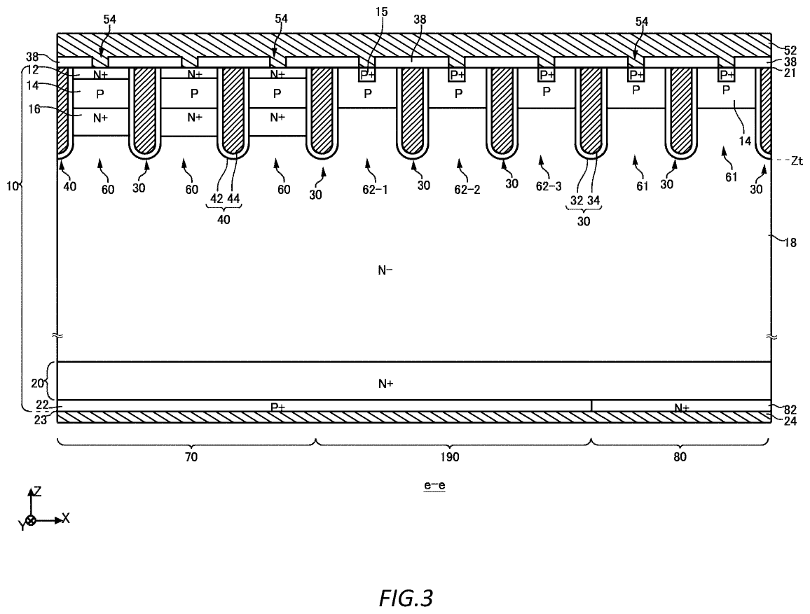

FIG. 3 illustrates a view showing an example of a cross section e-e in FIG. 2. FIG. 3 illustrates a structure according to a reference example. The cross section e-e is an XZ plane passing through the emitter region 12 and the cathode region 82. The cross section e-e includes the transistor portion 70, the connection region 190, and the diode portion 80. The semiconductor device 100 of this example includes the semiconductor substrate 10, the interlayer dielectric film 38, the emitter electrode 52, and the collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with the contact hole 54 described in FIG. 2.

The emitter electrode 52 is provided on the upper side of the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the specification, the direction in which the emitter electrode 52 is connected to the collector electrode 24 (the Z axis direction) is referred to as a depth direction.

The semiconductor substrate 10 includes an N type or N− type drift region 18. The drift region 18 is provided in each of the transistor portion 70, the diode portion 80, and the connection region 190.

In the mesa portion 60 of the transistor portion 70, an emitter region 12 of N+ type and a base region 14 of P type are provided in order from an upper surface 21 side of the semiconductor substrate 10. The drift region 18 is provided below the base region 14. The mesa portion 60 may be provided with an N+ type of accumulation region 16. The accumulation region 16 is arranged between the base region 14 and the drift region 18.

The emitter region 12 is exposed on the upper surface 21 of the semiconductor substrate 10 and is provided in contact with gate trench portion 40. The emitter region 12 may be in contact with the trench portions on both sides of the mesa portion 60. The emitter region 12 has a higher doping concentration than the drift region 18. On the XZ plane passing through the contact region 15, the contact region 15 is provided instead of the emitter region 12.

The base region 14 is provided below the emitter region 12. The base region 14 of this example is provided in contact with the emitter region 12. The base region 14 may be in contact with the trench portions on both sides of the mesa portion 60.

The accumulation region 16 is provided below the base region 14. The accumulation region 16 is an N+ type region with a higher doping concentration than the drift region 18. That is, the accumulation region 16 has a higher donor concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover a whole lower surface of the base region 14 in each mesa portion 60.

The mesa portion 61 of the diode portion 80 is provided with the P type of base region 14 in contact with the upper surface 21 of the semiconductor substrate 10. The drift region 18 is provided below the base region 14. In the mesa portion 61, the accumulation region 16 may be provided below the base region 14. In addition, the contact region 15 may be provided below the contact hole 54 on the upper surface 21 of the mesa portion 61. By providing the contact region 15, a contact resistance between the mesa portion 61 and the emitter electrode 52 can be reduced.

The mesa portion 62 of the connection region 190 is provided with the P type of base region 14 in contact with the upper surface 21 of the semiconductor substrate 10. The drift region 18 is provided below the base region 14. In the mesa portion 62, the accumulation region 16 may be provided below the base region 14. In addition, the contact region 15 may be provided below the contact hole 54 on the upper surface 21 of the mesa portion 62.

In each of the transistor portion 70, the diode portion 80, and the connection region 190, the buffer region 20 of the N+ type may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak indicates a doping concentration at the local maximum of the concentration peak. In addition, as the doping concentration of the drift region 18, an average value of doping concentrations in the region where the doping concentration distribution is substantially flat may be used.

The buffer region 20 may have two or more concentration peaks in the depth direction (Z axis direction) of the semiconductor substrate 10. The concentration peak of the buffer region 20 may be provided at the same depth position as, for example, a chemical concentration peak of hydrogen (a proton) or phosphorous. The buffer region 20 malfunction as a field stopper layer which prevents a depletion layer expanding from the lower end of the base region 14 from reaching the collector region of the P+ type 22 and the cathode region of the N+ type 82.

In the transistor portion 70, the collector region of the P+ type 22 is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. In the connection region 190, the collector region 22 may be provided or the cathode region 82 may be provided below the buffer region 20. In this example, the collector region 22 is provided below all the mesa portions 62.

A donor concentration of the cathode region 82 is higher than a donor concentration of the drift region 18. A donor of the cathode region 82 is, for example, hydrogen or phosphorous. Note that an element serving as a donor and an acceptor in each region is not limited to the above described example. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

On the upper surface 21 side of the semiconductor substrate 10, one or more gate trench portions 40 and one or more dummy trench portions 30 are provided at intervals in the X axis direction. Each trench portion is provided to pass through the base region 14 from the upper surface 21 of the semiconductor substrate 10 to below the base region 14. In a region where at least any one of the emitter region 12, the contact region 15, and the accumulation region 16 is provided, each trench portion also passes through the doping regions of these. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

As described above, the transistor portion 70 is provided with the gate trench portion 40 and the dummy trench portion 30. In the diode portion 80 and the connection region 190, the dummy trench portion 30 is provided, and the gate trench portion 40 is not provided.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 of this example are covered with the interlayer dielectric film 38 on the upper surface 21 of the semiconductor substrate 10. It is noted that the bottoms of the dummy trench portion 30 and the gate trench portion 40 may be formed in a curved-surface shape (a curved-line shape in the cross section) convexly downward. In the present specification, a depth position of a lower end of the gate trench portion 40 is referred to as Zt.

In the reference example of FIG. 3, the intervals of the trench portions in the X axis direction (that is, the widths of the mesa portions) are the same. In addition, the depths of the trench portions in the Z axis direction (that is, the lower end position Zt) are also the same. In the semiconductor device 100 including the trench portion as in this example, when a high voltage is applied, avalanche breakdown easily occurs in the vicinity of the lower end of the trench portion where an electric field concentrates. The collector region 22 of the P type is provided on the lower surface 23 of the transistor portion 70, and for example, a PNP transistor constituted by the base region 14, the drift region 18, and the collector region 22 is formed. When a structure such as the interval of the trench portions and the depth of the trench portion is the same between the transistor portion 70 and the diode portion 80, the avalanche breakdown voltage of the transistor portion 70 becomes lower than the avalanche breakdown voltage of the diode portion 80 due to the influence of the current amplification of the PNP transistor. The avalanche breakdown voltage refers to a voltage at which the avalanche breakdown first occurs at any place when a voltage between the collector electrode 24 and the emitter electrode 52 is gradually raised and each voltage is applied for a sufficiently long time. That is, the avalanche breakdown voltage refers to a static breakdown voltage.

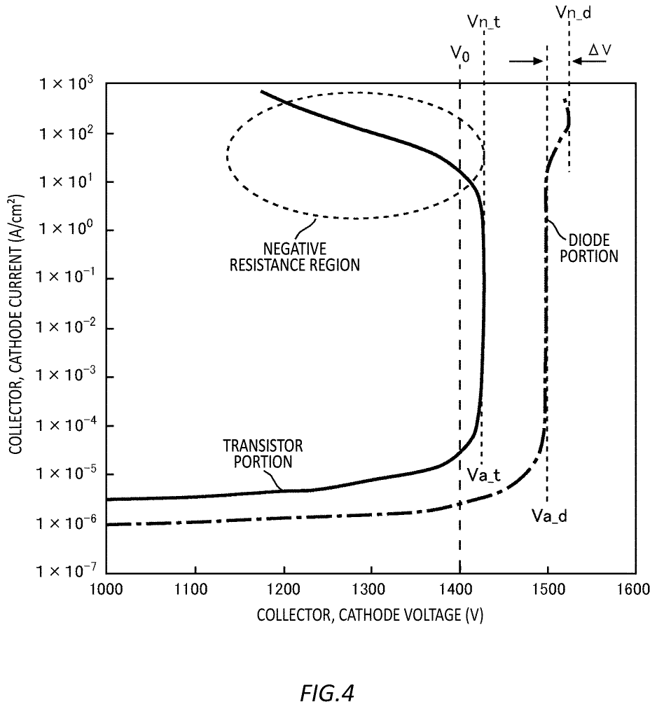

FIG. 4 is an example of current density-voltage characteristics of the transistor portion 70 and the diode portion 80 according to the reference example. FIG. 4 illustrates transition of a collector current in a case where the collector voltage of the transistor portion 70 is gradually raised when a gate voltage is 0 V or less, and transition of a cathode current in a case where the cathode voltage of the diode portion 80 is gradually raised. The collector voltage and the cathode voltage are voltages between the collector electrode 24 and the emitter electrode 52. The collector current and the cathode current are currents flowing through the collector electrode 24.

When the collector voltage of the transistor portion 70 reaches an avalanche breakdown voltage Va_t of the transistor portion 70, the avalanche breakdown occurs at the place where the breakdown voltage is low in the transistor portion 70, and the collector current rapidly rises. Similarly, when the cathode voltage of the diode portion 80 reaches an avalanche breakdown voltage Va_d of the diode portion 80, the avalanche breakdown occurs in the diode portion 80, and the cathode current rapidly rises. The semiconductor device 100 is designed such that both the avalanche breakdown voltage Va_t of the transistor portion 70 and the avalanche breakdown voltage Va_d of the diode portion 80 are larger than a specification value V of the breakdown voltage of the semiconductor device 100.

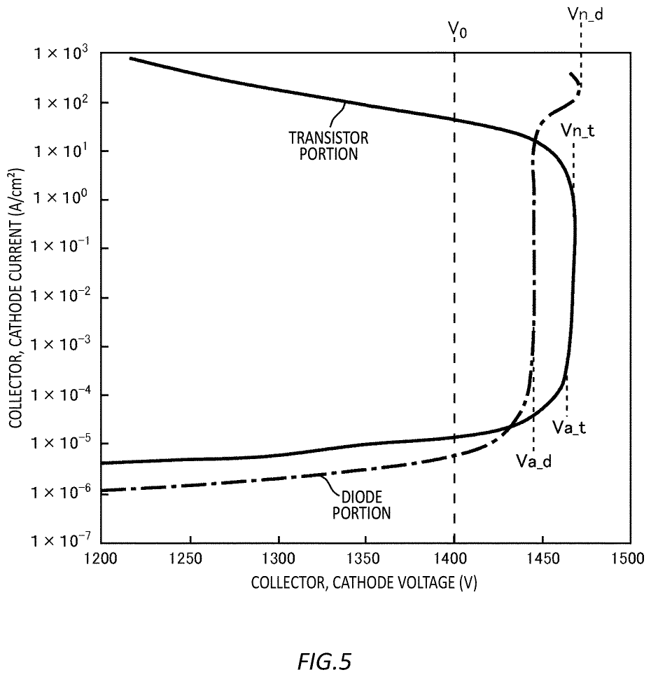

The avalanche breakdown voltage Va_t of the transistor portion 70 may be defined as a minimum voltage among the voltages of portions where the collector voltage is substantially constant (flat) with respect to an increase in the collector current in the current density-voltage characteristics illustrated in FIG. 5. The current density-voltage characteristics may be measured in an ambient temperature environment at room temperature (25° C.). The avalanche breakdown voltage Va_d of the diode portion 80 may be defined as a minimum voltage among the voltages of portions where the cathode voltage is substantially constant (flat) in the current density-voltage characteristics illustrated in FIG. 5. The term “substantially flat” means that, for example, fluctuation in voltage is 20 V or less while the current is fluctuating by 100 times.

As another example of the definition method, the avalanche breakdown voltage Va_t of the transistor portion 70 may be defined as a value of the collector voltage at a preset value of the collector current among the voltages of portions where the waveform of the collector voltage is substantially constant (flat) with respect to the increase in the collector current in the current density-voltage characteristics illustrated in FIG. 5. The avalanche breakdown voltage Va_d of the diode portion 80 may be defined as a value of the cathode voltage at a preset value of the cathode current among the voltages of portions where the cathode voltage is substantially constant (flat) with respect to the increase in the cathode current in the current density-voltage characteristics illustrated in FIG. 5. As an example, in the current density-voltage characteristics illustrated in FIG. 5, the collector voltage or the cathode voltage when the collector current or the cathode current is 1×10⁻³ (A/cm²) may be set as the avalanche breakdown voltage Va_t or the avalanche breakdown voltage Va_d. The preset value of the collector current or the cathode current may be 1×10⁻⁴ (A/cm²) or more or 1×10⁰ (A/cm²) or less in the current density-voltage characteristics illustrated in FIG. 5.

When the avalanche breakdown occurs in the transistor portion 70 and the current density of the collector current increases to reach a negative resistance region, the current increase cannot be suppressed, and the semiconductor device 100 is broken down. Similarly, also in the diode portion 80, when the current density of the cathode current reaches the negative resistance region (not illustrated in FIG. 4), the current increase cannot be suppressed, and the semiconductor device 100 is broken down.

In the transistor portion 70, a voltage that can rise from the voltage Va_t at which the avalanche breakdown occurs to the voltage Vn_t reaching the negative resistance region (Vn_t-Va_t) is approximately several volts, and a collector current that can rise is also small. When the temperature of the semiconductor substrate 10 rises, the voltage Vn_t reaching the negative resistance region can also rise, but in the transistor portion 70, the voltage and the current that can rise until reaching the negative resistance region from the avalanche breakdown are small, and thus the temperature of the semiconductor substrate 10 cannot be sufficiently raised, and the negative resistance region is easily reached.

On the other hand, in the diode portion 80, a voltage that can rise from the voltage Va_d at which the avalanche breakdown occurs to the voltage Vn_d reaching the negative resistance region (ΔV=Vn_d−Va_d) is relatively large, and a cathode current that can rise is also relatively large. Therefore, as compared with the transistor portion 70, the diode portion 80 is less likely to reach the negative resistance region even when the avalanche breakdown occurs, and the breakdown of the semiconductor device 100 can be suppressed.

The voltage Vn_d at which the diode portion 80 reaches the negative resistance region is a voltage at which the cathode voltage turns from increase to decrease when the cathode current of the diode portion 80 increases. The voltage Vn_d may be the maximum value of the cathode voltage in the characteristics illustrated in FIG. 5. The voltage Vn_t at which the transistor portion 70 reaches the negative resistance region is a voltage at which the collector voltage (collector-emitter voltage) turns from increase to decrease when the collector current of the transistor portion 70 increases. The voltage Vn_t may be the maximum value of the collector voltage in the characteristics illustrated in FIG. 5.

In the reference example illustrated in FIG. 4, the avalanche breakdown voltage Va_t of the transistor portion 70 is smaller than the avalanche breakdown voltage Va_d of the diode portion 80. Therefore, the transistor portion 70 first undergoes the avalanche breakdown. When the transistor portion 70 undergoes the avalanche breakdown, the negative resistance region is instantly reached, and the semiconductor device 100 is broken down.

FIG. 5 is an example of the current density-voltage characteristics of the transistor portion 70 and the diode portion 80 according to the embodiment. The avalanche breakdown voltage Va_d in the diode portion 80 of this example is smaller than the avalanche breakdown voltage Va_t in the transistor portion 70. Accordingly, the avalanche breakdown can be caused to occur in the diode portion 80 before the transistor portion 70. Therefore, when avalanche breakdown has occurred, it is possible to suppress instantly reaching the negative resistance region.

In this example, the avalanche breakdown voltage Va_d in the diode portion 80 is 0.7 times or more and less than 1 time the avalanche breakdown voltage Va_t in the transistor portion 70. By reducing the avalanche breakdown voltage Va_d of the diode portion 80, the avalanche breakdown in the transistor portion 70 can be easily suppressed. The avalanche breakdown voltage Va_d may be 0.98 times or less, 0.96 times or less, or 0.9 times or less the avalanche breakdown voltage Va_t. When the avalanche breakdown voltage Va_d of the diode portion 80 is excessively reduced, the avalanche breakdown voltage of the semiconductor device 100 is lowered. The avalanche breakdown voltage Va_d may be 0.75 times or more, 0.8 times or more, or 0.85 times or more the avalanche breakdown voltage Va_t.

The avalanche breakdown voltage Va_d of the diode portion 80 is larger than the specification value of the avalanche breakdown voltage V₀ of the semiconductor device 100. The avalanche breakdown voltage Va_d may be larger than the average value of the specification value V₀ of the avalanche breakdown voltage and the avalanche breakdown voltage Va_t in the transistor portion 70. The avalanche breakdown voltage Va_d of the diode portion 80 can be adjusted by the interval in the X axis direction of the trench portions in the diode portion 80 (or the width of the mesa portion 61 in the X axis direction), the depth of the trench portion in the diode portion 80, and the like.

The voltage Vn_d at which the diode portion 80 reaches the negative resistance region may be equal to or larger than the avalanche breakdown voltage Va_t of the transistor portion 70, or may be larger than the avalanche breakdown voltage Va_t of the transistor portion 70. The voltage Vn_d at which the diode portion 80 reaches the negative resistance region may be equal to or larger than the voltage Vn_t at which the transistor portion 70 reaches the negative resistance region. Accordingly, the transistor portion 70 is prevented from reaching the negative resistance region first. The voltage Vn_d at which the diode portion 80 reaches the negative resistance region may be smaller than or may be equal to the voltage Vn_t at which the transistor portion 70 reaches the negative resistance region.

The current density-voltage characteristics of the transistor portion 70 and the diode portion 80 may be calculated by using a general device simulation. The device simulation may be performed by solving Poisson's equation and a current continuity equation regarding electrons and holes under predetermined boundary conditions or initial conditions. As the current density-voltage characteristics of the transistor portion 70, the current density-voltage characteristics may be calculated for a structure simulating only the transistor portion 70.

Alternatively, calculation may be performed in a structure simulating both the transistor portion 70 and the diode portion 80, and the current density-voltage characteristics regarding only the transistor portion 70 may be extracted. As the current density-voltage characteristics of the diode portion 80, the current density-voltage characteristics may be calculated for a structure simulating only the diode portion 80. Alternatively, calculation may be performed in the structure simulating both the transistor portion 70 and the diode portion 80, and the current density-voltage characteristic regarding only the diode portion 80 may be extracted.

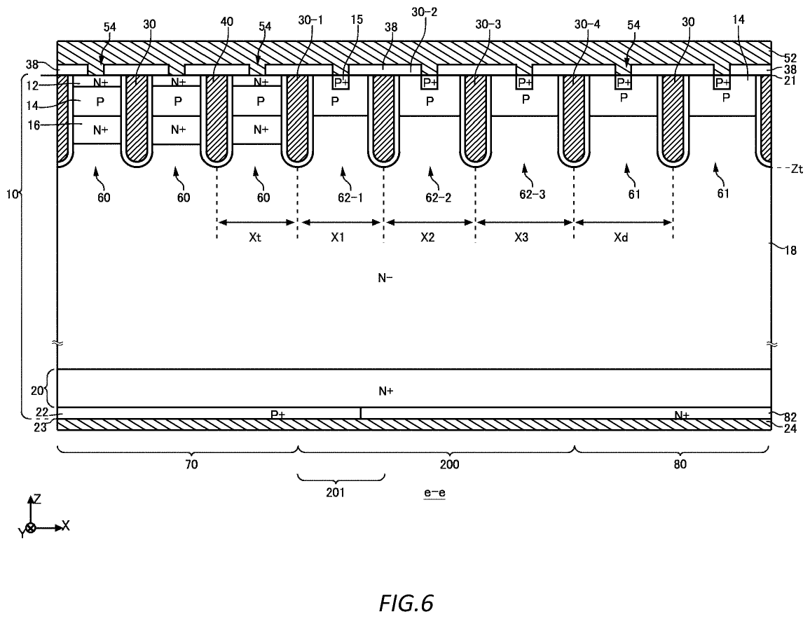

FIG. 6 illustrates an example of the cross section e-e according to the embodiment. In this example, the interval of the trench portions in the diode portion 80 is different from that of the reference example of FIG. 3. In this example, an intermediate region 200 may be provided instead of the connection region 190 in the reference example illustrated in FIG. 3. The interval of the trench portions in the X axis direction is different between the intermediate region 200 and the connection region 190. Other structures are similar to those of the examples described in FIGS. 1 to 3. The intermediate region 200 is arranged between the diode portion 80 and the transistor portion 70 in the X axis direction. A plurality of trench portions are provided in the intermediate region 200.

In the top view, a region including the mesa portion 60 provided with the emitter region 12 and the trench portion adjacent to the mesa portion 60 is defined as the transistor portion 70. The collector region 22 is provided on the lower surface of the transistor portion 70.

In the top view, a region including the mesa portion 61 not provided with the emitter region 12 and the trench portion adjacent to the mesa portion 61 is defined as the diode portion 80. The cathode region 82 is provided on the lower surface of the diode portion 80. The interval in the X axis direction of the plurality of trench portions in the diode portion 80 is a constant value Xd. In addition, the lengths in the Z axis direction of the plurality of trench portions in the diode portion 80 are also constant (the depth position Zt of the lower end). The avalanche breakdown voltage Va_d in the diode portion 80 is smaller than the avalanche breakdown voltage Va_t in the transistor portion 70.

In the top view, a region including the mesa portion 62 not provided with the emitter region 12 and the trench portion adjacent to the mesa portion 62 is defined as the intermediate region 200. At least one of the collector region 22 or the cathode region 82 is provided on the lower surface 23 of the intermediate region 200. One of the collector region 22 and the cathode region 82 may be provided on the lower surface 23 of the intermediate region 200 from a position in contact with the transistor portion 70 to a position in contact with the diode portion 80. In another example, on the lower surface of the intermediate region 200, the collector region 22 may be provided in a region in contact with the transistor portion 70, and the cathode region 82 may be provided in a region in contact with the diode portion 80. In this case, a boundary between the collector region 22 and the cathode region 82 is arranged in the intermediate region 200.

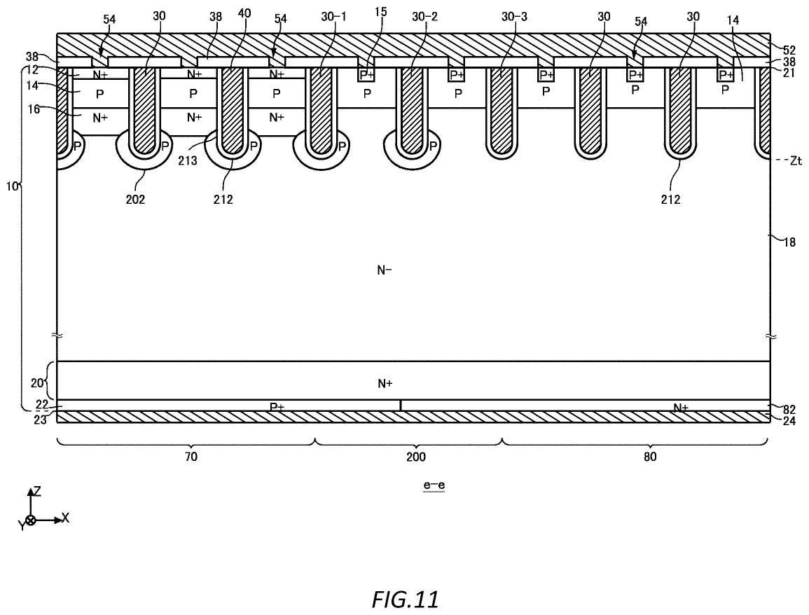

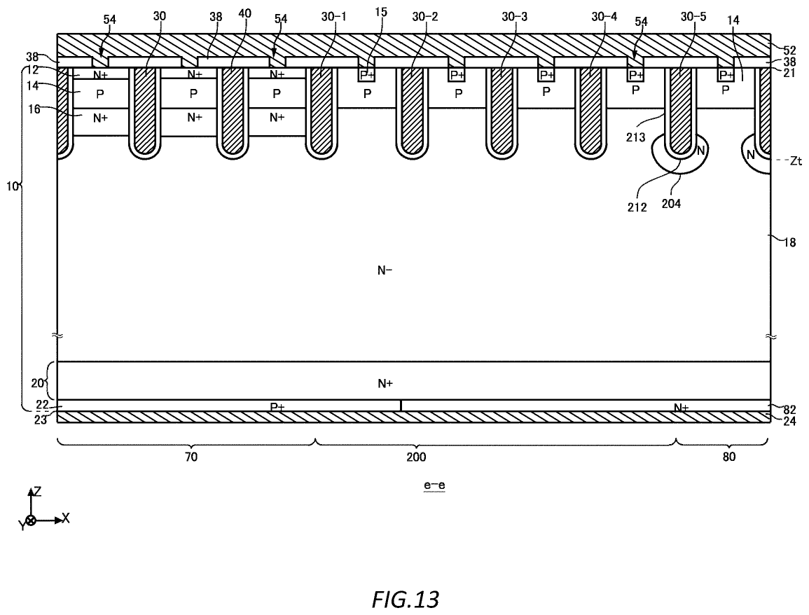

A boundary between the intermediate region 200 and the transistor portion 70 is a center in the X axis direction of a trench portion closest to the diode portion 80 among the trench portions in contact with the emitter region 12 (in this example, a dummy trench portion 30-1). The trench portion of the intermediate region 200 has a structure different from that of the trench portion of the diode portion 80. For example, the trench portion of the intermediate region 200 is different from the trench portion of the diode portion 80 in at least one of the interval of adjacent trench portions or the depth of the trench portion. Alternatively, the presence or absence of a first lower end region 202 (see FIG. 11) or a second lower end region 204 (see FIG. 13) may be different between the trench portion of the intermediate region 200 and the trench portion of the diode portion 80. A boundary between the intermediate region 200 and the diode portion 80 is a center in the X axis direction of a trench portion at the boundary where the structure changes (in this example, a dummy trench portion 30-4). The avalanche breakdown voltage of the intermediate region 200 may be larger than the avalanche breakdown voltage of the diode portion 80 and smaller than the avalanche breakdown voltage of the transistor portion 70. In each example of the present specification, the intermediate region 200 may not be provided. In this case, the transistor portion 70 and the diode portion 80 are provided in contact with each other.

Each of the diode portion 80, the transistor portion 70, and the intermediate region 200 includes a plurality of trench portions arranged at intervals along the array direction (X axis direction) on the upper surface 21 of the semiconductor substrate 10.

At least some of the trench portions in the transistor portion 70 are arranged at a first interval Xt in the X axis direction. The first interval Xt may be the maximum interval among the intervals of the trench portions in the transistor portion 70. In this example, all the trench portions in the transistor portion 70 are arranged at the first interval Xt.

At least some of the trench portions in the diode portion 80 are arranged at a second interval Xd larger than the first interval Xt in the X axis direction. In this example, all the trench portions of the diode portion 80 are arranged at the second interval Xd.

By increasing the second interval Xd of the trench portions in the diode portion 80, carriers in a wider region flow toward one trench portion. Therefore, in the diode portion 80, an electric field easily concentrates in one trench portion, and the avalanche breakdown voltage decreases. In this example, the second interval Xd of the trench portions in the diode portion 80 is set such that the avalanche breakdown voltage Va_d in the diode portion 80 is less than 1 time and 70% or more of the avalanche breakdown voltage Va_t in the transistor portion 70.

The second interval Xd of the trench portions in the diode portion 80 may be larger than the first interval Xt of the trench portions in the transistor portion 70, may be 1.2 times or more, may be 2 times or more, may be 3 times or more, or may be 5 times or more the first interval Xt. As an example, the first interval Xt is 2.5 μm or less, and the second interval Xd is 5 μm or more. However, when the second interval Xd is made excessively large, the breakdown voltage of the diode portion 80 becomes excessively small, and thus the second interval Xd may be 50 μm or less or may be 30 μm or less.

The intermediate region 200 includes a plurality of trench portions. The intermediate region 200 of this example includes a plurality of dummy trench portions 30. As described above, the dummy trench portion 30-1 is arranged at a boundary between the transistor portion 70 and the intermediate region 200. The center of the dummy trench portion 30-1 in the X axis direction is set as the boundary position between the transistor portion 70 and the intermediate region 200. As described above, the dummy trench portion 30-4 is arranged at a boundary between the diode portion 80 and the intermediate region 200. The center of the dummy trench portion 30-4 in the X axis direction is set as the boundary position between the diode portion 80 and the intermediate region 200. One or more dummy trench portions 30 may be arranged between the dummy trench portion 30-1 and the dummy trench portion 30-4, and the other dummy trench portions 30 may not be arranged. In the example of FIG. 6, the dummy trench portion 30-2 and the dummy trench portion 30-3 are arranged between the dummy trench portion 30-1 and the dummy trench portion 30-4.

The intermediate region 200 includes one or more mesa portions 62. In this example, the mesa portion 62-1 is arranged adjacent to the transistor portion 70, and the mesa portion 62-3 is arranged adjacent to the diode portion 80. One or more mesa portions 62 may be arranged between the mesa portion 62-1 and the mesa portion 62-3, and the other mesa portions 62 may not be arranged. In the example of FIG. 6, the mesa portion 62 -2 is arranged between the mesa portion 62-1 and the mesa portion 62-3.

In the intermediate region 200 of this example, a trench interval monotonically increases when approaching the diode portion 80 from the dummy trench portion 30-1 to the dummy trench portion 30-4. That is, in the intermediate region 200 of this example, a mesa width monotonically increases when approaching the diode portion 80 from the mesa portion 62-1 to the mesa portion 62-3. The trench interval is a distance between the center positions of adjacent trench portions in the X axis direction. The mesa width is a width of a region sandwiched between two adjacent trench portions in the X axis direction. The description “a trench interval monotonically increases” means that in a direction from the dummy trench portion 30-1 toward the dummy trench portion 30-4, the trench interval increases at least at one place and there is no place where the trench interval decreases. That is, a region where the trench interval does not change may be included in the direction from the dummy trench portion 30-1 toward the dummy trench portion 30-4.

In the example of FIG. 6, the trench interval between a dummy trench portion 30-k and a dummy trench portion 30-k+1 is referred to as Xk. Here, k is an integer of 1 or more. In addition, the dummy trench portion 30-k+1 is arranged adjacent to the dummy trench portion 30-k with the dummy trench portion 30-k+1 being closer to the diode portion 80 side. The trench interval Xk may monotonically increase according to an increase in k. With respect to the avalanche breakdown voltage in one mesa portion 62, the trench interval Xk monotonically increases, so that the avalanche breakdown voltage can be gradually changed in the X axis direction. Accordingly, it is possible to prevent concentration of an electric field intensity on the intermediate region 200.

The intermediate region 200 includes a transistor side region 201 in contact with the transistor portion 70. In the transistor side region 201, one or more trench portions (the dummy trench portions 30 in this example) are arranged at the first interval Xt same as the trench interval in the transistor portion 70. In the example of FIG. 6, the trench interval X1 is equal to the first interval Xt. That is, a region from the dummy trench portion 30-1 to the dummy trench portion 30-2 is the transistor side region 201. A boundary position in the X axis direction between the cathode region 82 and the collector region 22 in the intermediate region 200 may be arranged in the transistor side region 201.

A trench interval X3 at a place closest to the diode portion 80 is larger than the trench interval X1. The trench interval X3 is smaller than the second interval Xd in the diode portion 80.

In the intermediate region 200, the trench interval may increase at one place, or the trench interval may increase at a plurality of places. In this example, Xt=X1<X2<X3<Xd is satisfied. That is, the trench interval in the X axis direction of the plurality of trench portions in the intermediate region 200 of this example increases when approaching the diode portion 80. X3=Xd may be satisfied. In this case, the diode portion 80 is provided up to the dummy trench portion 30-3.

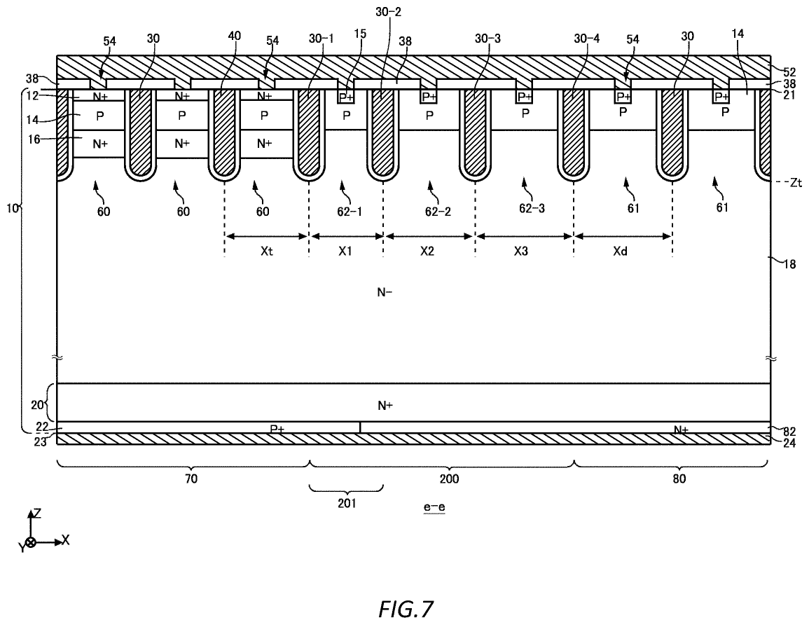

FIG. 7 illustrates another example of the cross section e-e according to the embodiment. In this example, the trench interval X1 in the transistor side region 201 is different from that of the example of FIG. 6. Other structures may be similar to those of the example of FIG. 6. The trench interval X1 in the transistor side region 201 of this example is smaller than the first interval Xt in the transistor portion 70. In the example of FIG. 7, the transistor side region 201 includes two trench portions, but may include more trench portions. Also in this case, each trench interval Xk in the transistor side region 201 is smaller than the first interval Xt. Each trench interval Xk in the transistor side region 201 may be constant, or may monotonically increase toward the diode portion 80.

In the intermediate region 200, a portion adjacent to the transistor portion 70 allows a current to flow relatively easily. Therefore, by reducing the trench interval in the transistor side region 201, the breakdown voltage at the place can be increased to suppress the breakdown of the semiconductor device 100.

The trench interval X2 of the trench portions, which are adjacent to the transistor side region 201, in the intermediate region 200 is larger than the trench interval X1 in the transistor side region 201. The trench interval X2 may be the same as the first interval Xt, or may be smaller or larger than the first interval Xt. The trench interval X1 in the transistor side region 201 is the smallest trench interval in the intermediate region 200. In this example, Xt>X1<X2<X3<Xd is satisfied. X3=Xd may be satisfied. The boundary position in the X axis direction between the collector region 22 and the cathode region 82 may be arranged in a region from below the dummy trench portion 30-1 to below the dummy trench portion 30-2.

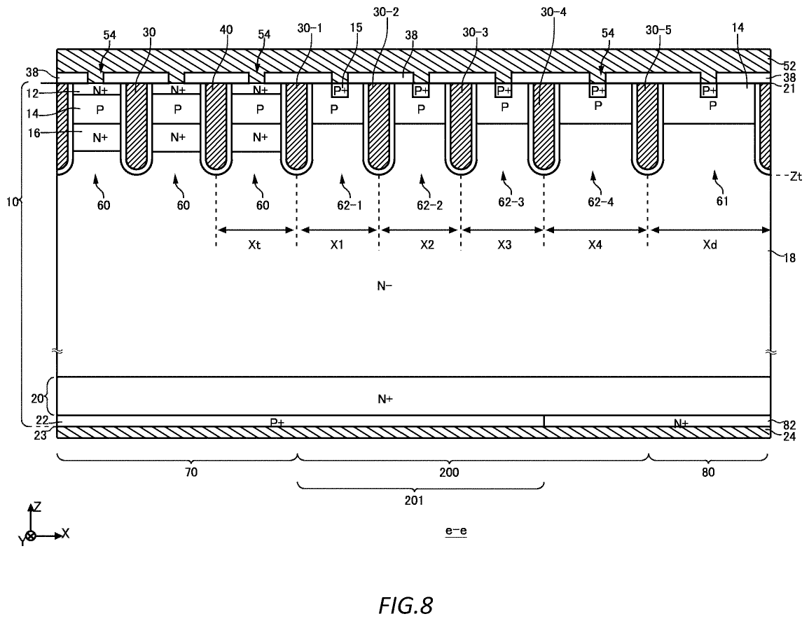

FIG. 8 illustrates another example of the cross section e-e according to the embodiment. In this example, the configuration of the transistor side region 201 is different from that of the example of FIG. 6. Other structures may be similar to those of the example of FIG. 6. The transistor side region 201 of this example includes three or more trench portions. In FIG. 8, a region from the dummy trench portion 30-1 to the dummy trench portion 30-4 is the transistor side region 201. Similarly to the example of FIG. 6, each trench interval (X1, X2, X3 in this example) in the transistor side region 201 may be the same as the first interval Xt, or may be smaller than the first interval Xt. The boundary position between the cathode region 82 and the collector region 22 is arranged below the dummy trench portion 30-4, which is closest to the diode portion 80, among the trench portions of the transistor side region 201.

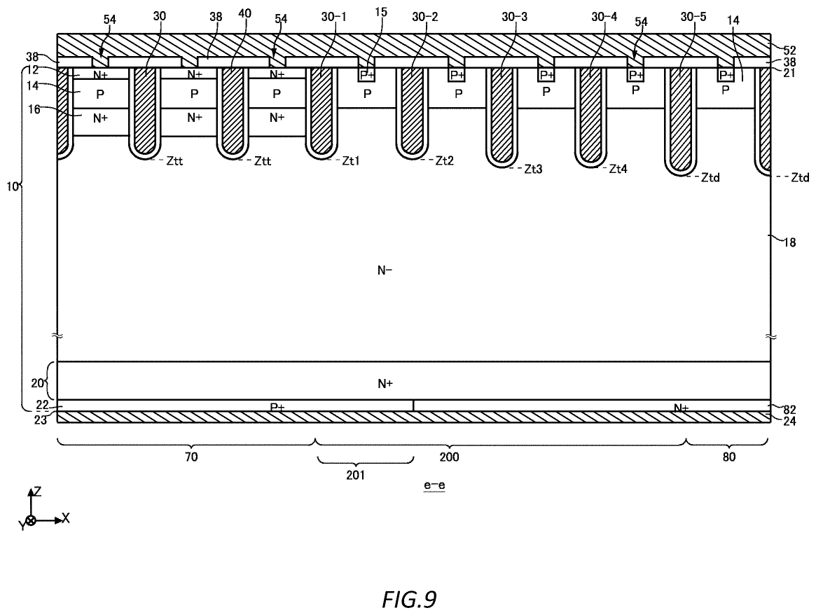

FIG. 9 illustrates another example of the cross section e-e according to the embodiment. In this example, the length in the Z axis direction of the trench portion of the diode portion 80 is different from that of the example described in FIGS. 3 to 8. Further, in this example, the intermediate region 200 is provided instead of the connection region 190 in the reference example illustrated in FIG. 3. In the intermediate region 200 of this example, the length of the trench portion in the Z axis direction is different from that of the example described in FIGS. 6 to 8. The other structure (for example, the trench interval Xk) in the intermediate region 200 may be similar to that of any example described in FIGS. 6 to 8, or may be the same as the connection region 190 described in FIG. 3.

At least some of the trench portions in the transistor portion 70 are arranged with a first length Ztt in the Z axis direction. The first length Ztt may be the maximum length among the lengths of the trench portions in the transistor portion 70. In this example, all the trench portions in the transistor portion 70 have the first length Ztt.

At least some of the trench portions in the diode portion 80 have a second length Ztd larger than the first length Ztt in the Z axis direction. In this example, all the trench portions of the diode portion 80 have the second length Ztd.

By increasing the second length Ztd of the trench portion in the diode portion 80, the current easily concentrates at the lower end of the trench portion of the diode portion, and the avalanche breakdown voltage decreases. In this example, the second length Ztd of the trench portion in the diode portion 80 is set such that the avalanche breakdown voltage Va_d in the diode portion 80 is less than 1 time and 70% or more of the avalanche breakdown voltage Va_t in the transistor portion 70. As described in FIGS. 6 to 8, when the trench interval Xd in the diode portion 80 and the trench interval Xt in the transistor portion 70 are further made different, the length of each trench portion and the trench interval are set such that the avalanche breakdown voltage Va_d in the diode portion 80 is less than 1 time and 70% or more of the avalanche breakdown voltage Va_t in the transistor portion 70.

The second length Ztd may be 1.5 times or more or may be 2 times or more the first length Ztt. However, when the second length Ztd is made excessively large, the breakdown voltage of the diode portion 80 becomes excessively small, and thus, the second length Ztd may be 5 times or less or may be 4 times or less the first length Ztt.

The intermediate region 200 includes a plurality of trench portions. The intermediate region 200 of this example includes a plurality of dummy trench portions 30. In this example, the dummy trench portion 30-1 is arranged at the boundary between the transistor portion 70 and the intermediate region 200, and the dummy trench portion 30-5 is arranged at the boundary between the diode portion 80 and the intermediate region 200. One or more dummy trench portions 30 may be arranged between the dummy trench portion 30-1 and the dummy trench portion 30-5, and the other dummy trench portions 30 may not be arranged. In the example of FIG. 9, the dummy trench portion 30-2, the dummy trench portion 30-3, and the dummy trench portion 30-4 are arranged between the dummy trench portion 30-1 and the dummy trench portion 30-5.

In the intermediate region 200 of this example, the length of the trench portion in the Z axis direction monotonically increases when approaching the diode portion 80 from the dummy trench portion 30-1 to the dummy trench portion 30-5. The description “the length of the trench portion monotonically increases” means that in a direction from the dummy trench portion 30-1 toward the dummy trench portion 30-5, the length of the trench portion increases at least at one place and there is no place where the length of the trench portion decreases. That is, a region where the length of the trench portion does not change may be included in the direction from the dummy trench portion 30-1 toward the dummy trench portion 30-5.

In the example of FIG. 9, the length of the dummy trench portion 30-k in the Z axis direction is defined as Ztk. Here, k is an integer of 1 or more. In addition, the dummy trench portion 30-k+1 is arranged adjacent to the dummy trench portion 30-k with the dummy trench portion 30-k+1 being closer to the diode portion 80 side. The length Ztk may monotonically increase according to an increase in k. The trench length Ztk monotonically increases, so that the avalanche breakdown voltage can be gradually changed in the X axis direction.

The intermediate region 200 includes a transistor side region 201 in contact with the transistor portion 70. In the transistor side region 201, one or more trench portions (the dummy trench portions 30 in this example) are arranged with the first length Ztt same as that of the transistor portion 70. In the example of FIG. 9, the trench lengths Zt1 and Zt2 are equal to the first length Ztt. That is, a region from the dummy trench portion 30-1 to the dummy trench portion 30-2 is the transistor side region 201. A boundary position in the X axis direction between the cathode region 82 and the collector region 22 in the intermediate region 200 may be arranged in the transistor side region 201.

A trench length Zt4 at a place closest to the diode portion 80 is larger than the trench length Zt1. The trench length Zt4 is smaller than the second length Ztd in the diode portion 80.

In the intermediate region 200, the trench length may increase at one place, or the trench length may increase at a plurality of places. In this example, Ztt=Zt1=Zt2<Zt3=Zt4<Ztd is satisfied. In another example, the trench lengths in the X axis direction of the plurality of trench portions in the intermediate region 200 may increase when approaching the diode portion 80. That is, Ztt=Zt1<Zt2<Zt3<Zt4<Ztd may be satisfied.

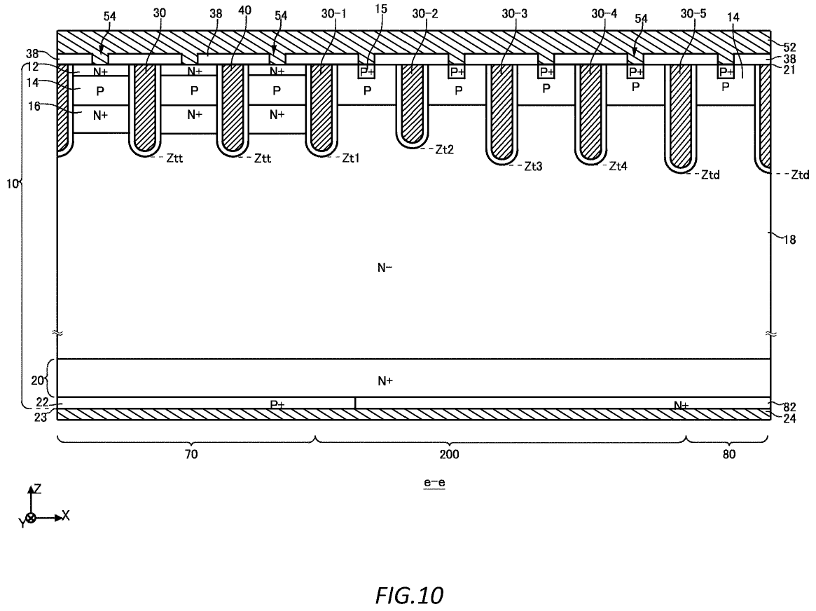

FIG. 10 illustrates another example of the cross section e-e according to the embodiment. In this example, the trench length of any trench portion in the transistor side region 201 is different from that of the example of FIG. 9. Other structures may be similar to those of the example of FIG. 9. The trench length (Zt2 in FIG. 10) of any trench portion in the transistor side region 201 of this example is smaller than the first length Ztt in the transistor portion 70.

In the example of FIG. 10, the trench length Zt2 of one dummy trench portion 30-2 in the transistor side region 201 is smaller than the first length Ztt. In another example, the transistor side region 201 may include a plurality of dummy trench portions 30 having a trench length smaller than the first length Ztt. The trench lengths of these dummy trench portions 30 may be constant or may monotonically increase toward the diode portion 80.

In the intermediate region 200, a portion adjacent to the transistor portion 70 allows a current to flow relatively easily. Therefore, by reducing the trench length in the transistor side region 201, the breakdown voltage at the place can be increased to suppress the breakdown of the semiconductor device 100.

The trench length Zt3 of the trench portion adjacent to the transistor side region 201 is larger than the trench length Zt2. The trench length Zt3 may be the same as the first interval Xt or may be larger than the first interval Xt. The trench length Zt2 of the transistor side region 201 is the smallest trench interval in the intermediate region 200. In this example, Ztt=Zt1>Zt2<Zt3=Zt4<Ztd is satisfied. The boundary position in the X axis direction between the collector region 22 and the cathode region 82 may be arranged in a region from below the dummy trench portion 30-1 to below the dummy trench portion 30-2.

FIG. 11 illustrates another example of the cross section e-e according to the embodiment. This example is different from the examples described in FIGS. 3 to 10 in that the first lower end region 202 is provided in the transistor portion 70 and the intermediate region 200. Similarly to the example described in FIG. 3, the trench interval Xt and the trench length may be constant in the transistor portion 70, the diode portion 80, and the intermediate region 200. The transistor portion 70, the diode portion 80, and the intermediate region 200 may have a trench interval similar to those of the examples described in FIGS. 6 to 8, or may have a trench length similar to those of the examples described in FIGS. 9 and 10.

The transistor portion 70 includes the first lower end region 202 of the P type provided in contact with the lower end 212 of at least one trench portion. The first lower end region 202 is provided so as to cover from the lower end 212 of the trench portion to a part of the side wall 213 of the trench portion. The first lower end region 202 of the transistor portion 70 of this example is in contact with the accumulation region 16. By providing the first lower end region 202, it is possible to reduce electric field strength at the lower end 212 of the trench portion of the transistor portion 70. The doping concentration of the first lower end region 202 may be lower or may be higher than the doping concentration of the base region 14. The doping concentration of the first lower end region 202 may be lower than that of the collector region 22 or may be lower than that of the contact region 15.

The first lower end region 202 may be provided in all the trench portions of the transistor portion 70. The first lower end regions 202 provided at the lower ends 212 of the respective trench portions may be separated from each other in the X axis direction as illustrated in FIG. 11, or may be connected to each other in the X axis direction.

The first lower end region 202 is not provided at the lower end 212 of at least one trench portion of the diode portion 80. That is, the lower end 212 of the trench portion is not in contact with a region of the P type. In this example, the lower end 212 of the trench portion is in contact with the drift region 18. The first lower end region 202 may not be provided at the lower ends 212 of all the trench portions of the diode portion 80.

By providing the first lower end region 202 in the transistor portion 70 and not providing the first lower end region 202 in the diode portion 80, the avalanche breakdown voltage of the transistor portion 70 can be increased and the avalanche breakdown voltage of the diode portion 80 can be relatively lowered. Even with such a structure, as illustrated in FIG. 5, the avalanche breakdown voltage of the diode portion 80 can be adjusted to less than 1 time and 70% or more of the avalanche breakdown voltage of the transistor portion 70. The avalanche breakdown voltage of the transistor portion 70 can be adjusted by the doping concentration of the first lower end region 202 or the like. In addition, two or more of the adjustment of the trench interval Xk described in FIGS. 6 to 8, the adjustment of the trench length described in FIGS. 9 and 10, and the adjustment using the first lower end region 202 described in FIG. 11 may be combined to adjust the avalanche breakdown voltage of the diode portion 80 to less than 1 time and 70% or more of the avalanche breakdown voltage of the transistor portion 70.

The first lower end region 202 is provided in the trench portion of the intermediate region 200 except for the dummy trench portion 30-3 arranged at the boundary with the diode portion 80. In the example of FIG. 11, the first lower end region 202 is provided in contact with the lower ends 212 of the dummy trench portion 30-1 and the dummy trench portion 30-2. The doping concentration of each first lower end region 202 of the intermediate region 200 is the same as the doping concentration of the first lower end region 202 of the transistor portion 70. In another example, the doping concentration of the first lower end region 202 of the intermediate region 200 may monotonically decrease when approaching the diode portion 80. The boundary position in the X axis direction between the collector region 22 and the cathode region 82 may be arranged in a region from below the dummy trench portion 30-1 to below the dummy trench portion 30-2.

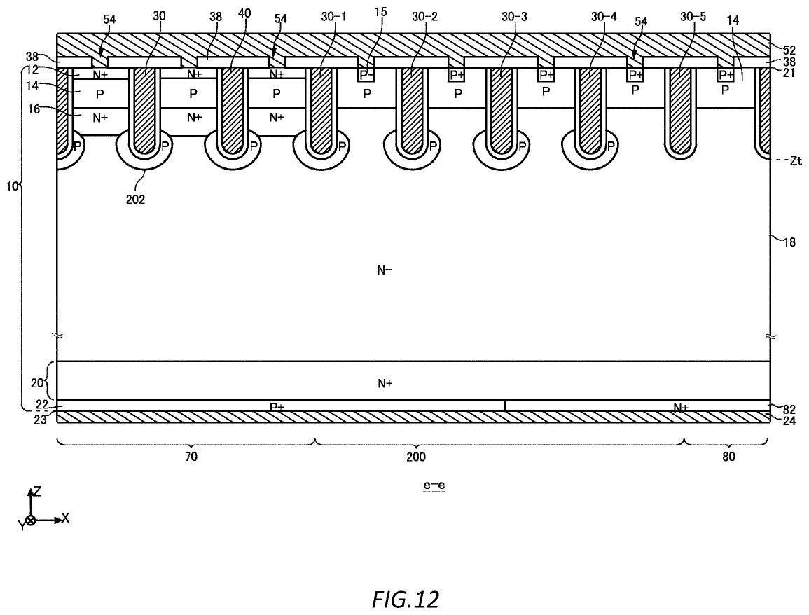

FIG. 12 illustrates another example of the cross section e-e according to the embodiment. In this example, the number of trench portions in the intermediate region 200 is different from that of the example of FIG. 11. Other structures are similar to those of the example of FIG. 11. The intermediate region 200 of this example includes three or more trench portions, each of which is provided with the first lower end region 202. In FIG. 12, the first lower end region 202 is provided in the four dummy trench portions 30 of the dummy trench portion 30-1 to the dummy trench portion 30-4.

FIG. 13 illustrates another example of the cross section e-e according to the embodiment. This example is different from the example described in FIGS. 3 to 12 in that the diode portion 80 is provided with the second lower end region 204. Similarly to the example described in FIG. 3, the trench interval Xt and the trench length may be constant in the transistor portion 70, the diode portion 80, and the intermediate region 200. The transistor portion 70, the diode portion 80, and the intermediate region 200 may have a trench interval similar to those of the examples described in FIGS. 6 to 8, or may have a trench length similar to those of the examples described in FIGS. 9 and 10. In addition, similarly to the examples described in FIGS. 11 and 12, the first lower end regions 202 may be provided with the transistor portion 70 and the intermediate region 200.

The diode portion 80 includes the second lower end region 204 of the N type provided in contact with the lower end 212 of at least one trench portion. The second lower end region 204 is provided so as to cover from the lower end 212 of the trench portion to a part of the side wall 213 of the trench portion. The lower end of the second lower end region 204 is arranged on the lower surface 23 side with respect to the lower end of the accumulation region 16. The doping concentration of the second lower end region 204 is higher than the doping concentration of the drift region 18. The doping concentration of the second lower end region 204 may be 2 times or more, may be 5 times or more, or may be 10 times or more the doping concentration of the drift region 18. The doping concentration of the second lower end region 204 may be lower than the doping concentration of the accumulation region 16. The doping concentration of the second lower end region 204 may be lower than the doping concentration of the cathode region 82. By providing the second lower end region 204, the electric field strength at the lower end 212 of the trench portion of the diode portion 80 is promoted, and the avalanche breakdown voltage in the diode portion 80 can be lowered.

Among the trench portions of the diode portion 80, half or more of the trench portions may be provided with the second lower end regions 204, 90% or more of the trench portions may be provided with the second lower end regions 204, or all the trench portions may be provided with the second lower end regions 204. The second lower end regions 204 provided at the lower ends 212 of the respective trench portions may be separated from each other in the X axis direction as illustrated in FIG. 13, or may be connected to each other in the X axis direction.

The second lower end region 204 is not provided at the lower end 212 of at least one trench portion of the transistor portion 70. That is, the lower end 212 of the trench portion is not in contact with an N type region with a higher doping concentration than the drift region 18. In this example, the lower end 212 of the trench portion is in contact with the drift region 18. The second lower end region 204 may not be provided at the lower ends 212 of all the trench portions of the transistor portion 70. The second lower end region 204 is not provided at the lower ends 212 of all the trench portions in the intermediate region 200.

The doping concentrations of respective second lower end regions 204 may be uniform. In another example, the doping concentrations of a plurality of second lower end regions 204 may be different from each other. As an example, the doping concentration of the second lower end region 204 at the center of the diode portion 80 in the X axis direction may be higher than the doping concentration of the second lower end region 204 at the end of the diode portion 80 in the X axis direction. Accordingly, the avalanche breakdown easily occurs in the vicinity of the center of the diode portion 80 separate from the transistor portion 70.

The boundary position between the collector region 22 and the cathode region 82 is arranged on the transistor portion 70 side with respect to the second lower end region 204. Accordingly, the collector region 22 of the P+ type and the second lower end region 204 of the N type can be arranged apart from each other, so as to suppress the movement of carriers between the collector region 22 and the second lower end region 204.

Also with the structure of this example, as illustrated in FIG. 5, the avalanche breakdown voltage of the diode portion 80 can be adjusted to less than 1 time and 70% or more of the avalanche breakdown voltage of the transistor portion 70. The avalanche breakdown voltage of the diode portion 80 can be adjusted by the doping concentration of the second lower end region 204 or the like. In addition, two or more of the adjustment of the trench interval Xk described in FIGS. 6 to 8, the adjustment of the trench length described in FIGS. 9 and 10, the adjustment using the first lower end region 202 described in FIGS. 11 and 12, and the adjustment using the second lower end region 204 described in FIG. 13 may be combined to adjust the avalanche breakdown voltage of the diode portion 80 to less than 1 time and 70% or more of the avalanche breakdown voltage of the transistor portion 70.

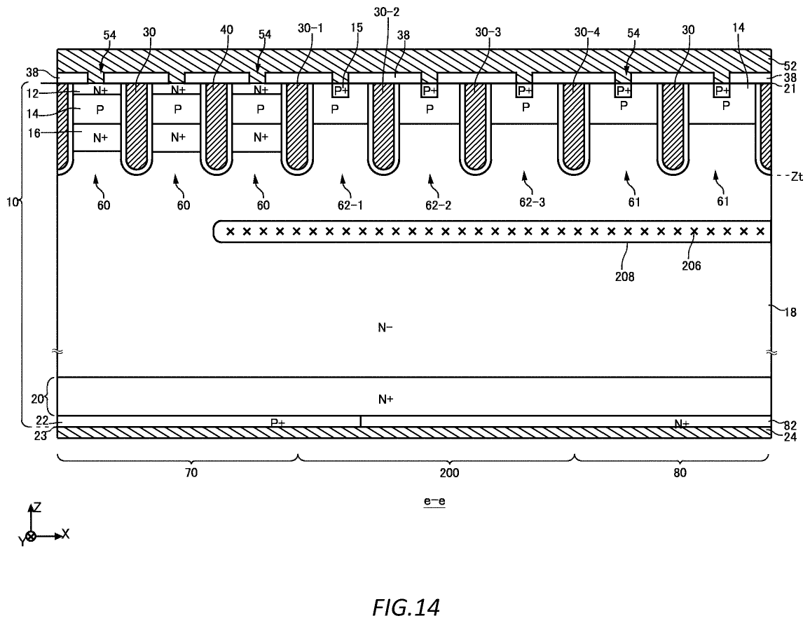

FIG. 14 illustrates another example of the cross section e-e according to the embodiment. This example is different from the examples described in FIGS. 3 to 13 in that a lifetime adjustment portion 208 is provided in the diode portion 80. Similarly to the example described in FIG. 3, the trench interval Xt and the trench length may be constant in the transistor portion 70, the diode portion 80, and the intermediate region 200. The transistor portion 70, the diode portion 80, and the intermediate region 200 may have a trench interval similar to those of the examples described in FIGS. 6 to 8, or may have a trench length similar to those of the examples described in FIGS. 9 and 10. Similarly to the examples described in FIGS. 11 and 12, the first lower end regions 202 may be provided in the transistor portion 70 and the intermediate region 200. Similarly to the example described in FIG. 13, the diode portion 80 may be provided with the second lower end region 204.

The lifetime adjustment portion 208 is arranged below the lower end of the trench portion on the upper surface 21 side of the semiconductor substrate 10. The lifetime adjustment portion 208 is a region in which a carrier lifetime indicates a minimum value in the depth direction of the semiconductor substrate 10. In a region where many lattice defects 206 remain, carriers are captured by the lattice defects 206, so that the lifetime of the carriers is shortened. By adjusting the lifetime of the carrier, characteristics such as the turn-off time of the semiconductor device 100 can be adjusted. In this example, by radiating a charged particle beam such as a helium ion beam to a predetermined depth position, the lattice defects 206 are formed in the vicinity of the depth position, and the lifetime adjustment portion 208 is formed. The lifetime adjustment portion 208 of this example is provided over the entire diode portion 80 in the X axis direction. The lifetime adjustment portion 208 may be provided to extend over the entire intermediate region 200 in the X axis direction. The lifetime adjustment portion 208 may also be provided to extend to a part of the transistor portion 70 in the X axis direction.

In the region where the lifetime adjustment portion 208 is provided, the carrier lifetime may be less than 10% and 0.001% or more as compared with the region where the lifetime adjustment portion 208 is not provided. For example, the carrier lifetime in the lifetime adjustment portion 208 is less than 10% and 0.001% or more as compared with a reference carrier lifetime at the center in the depth direction of the drift region 18 of the transistor portion 70. The carrier lifetime in the lifetime adjustment portion 208 may be 1% or less or may be 0.1% or less of the reference carrier lifetime. The carrier lifetime in the lifetime adjustment portion 208 may be 0.01% or more of the reference carrier lifetime.

As in the example in FIGS. 3 to 13, when the lifetime adjustment portion 208 is not provided, the carrier lifetime in the drift region 18 is substantially uniform. The term “substantially uniform” means that the carrier lifetime in the entire drift region 18 is distributed within a range of 100% or less and 10% or more with respect to the maximum value of the carrier lifetime of the drift region 18, for example. When the lifetime adjustment portion 208 is not provided, the carrier lifetime in the entire drift region 18 may be distributed within the range of 100% or less and 50% or more with respect to the maximum value of the carrier lifetime of the drift region 18.

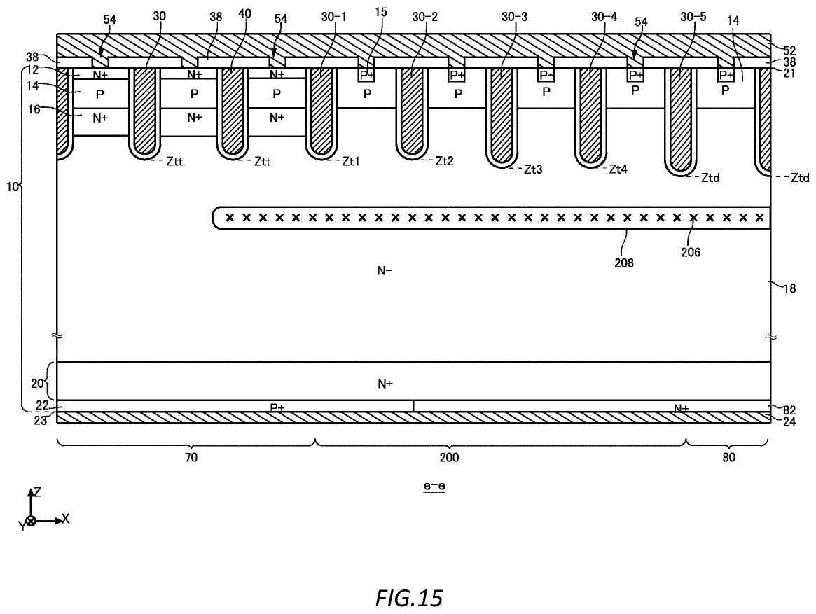

FIG. 15 illustrates another example of the cross section e-e according to the embodiment. In this example, the lifetime adjustment portion 208 is provided in the configuration illustrated in FIG. 9. The lifetime adjustment portion 208 may be provided in the configuration illustrated in FIG. 10.

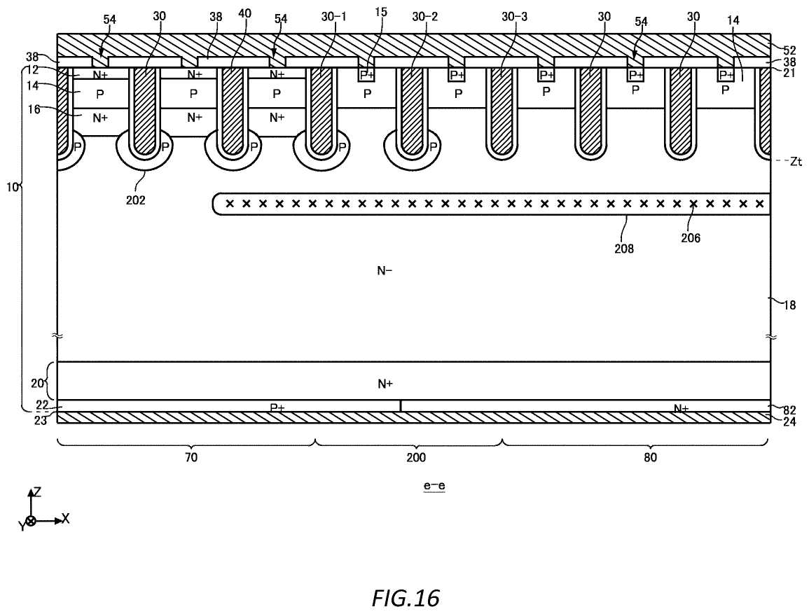

FIG. 16 illustrates another example of the cross section e-e according to the embodiment. In this example, the lifetime adjustment portion 208 is provided in the configuration illustrated in FIG. 11. The lifetime adjustment portion 208 may be provided in the configuration illustrated in FIG. 12.

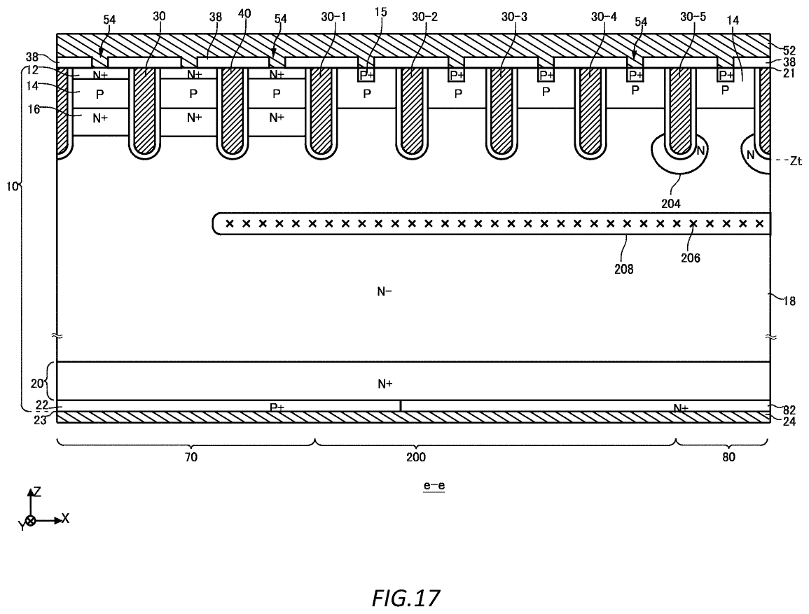

FIG. 17 illustrates another example of the cross section e-e according to the embodiment. In this example, the lifetime adjustment portion 208 is provided in the configuration illustrated in FIG. 13.

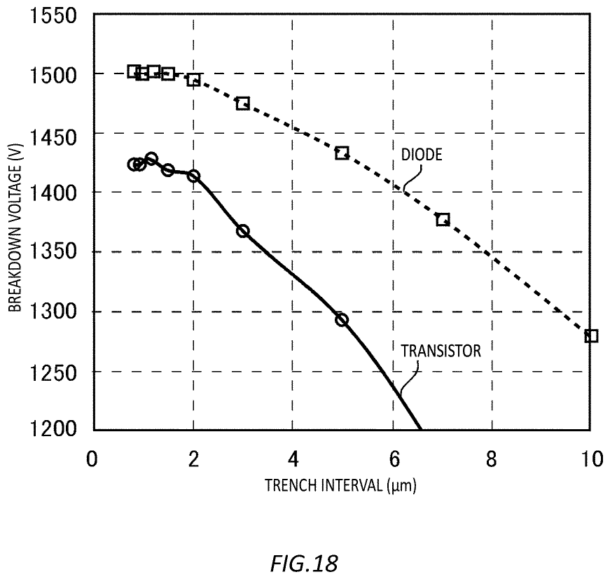

FIG. 18 illustrates the relationship between the trench interval in the transistor portion 70 and the diode portion 80 and the avalanche breakdown voltage in the transistor portion 70 and the diode portion 80. In FIG. 18, the measured value of each sample is indicated by a square plot and a circle plot. In both the transistor portion 70 and the diode portion 80, when the trench interval is increased, the avalanche breakdown voltage decreases. That is, the avalanche breakdown voltage can be adjusted by adjusting the trench interval. In this example, when the trench interval in the transistor portion 70 is 1 μm, the breakdown voltage of the transistor portion 70 is 1425 V. Meanwhile, when the trench interval in the diode portion 80 is 5.5 μm or more, the breakdown voltage of the diode portion 80 can be made smaller than 1425 V. The trench interval in the diode portion 80 may be 5.5 times or more, may be 6 times or more, or may be 10 times or more the trench interval in the transistor portion 70.

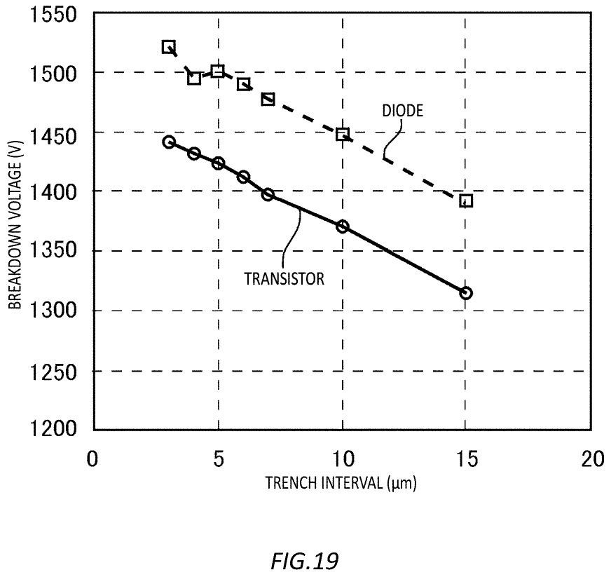

FIG. 19 illustrates a relationship between the trench length in the transistor portion 70 and the diode portion 80 and the avalanche breakdown voltage in the transistor portion 70 and the diode portion 80. In FIG. 19, the measured value of each sample is indicated by a square plot and a circle plot. In both the transistor portion 70 and the diode portion 80, when the trench length is increased, the avalanche breakdown voltage decreases. That is, the avalanche breakdown voltage can be adjusted by adjusting the trench length. In this example, when the trench length in the transistor portion 70 is 5 μm, the breakdown voltage of the transistor portion 70 is 1425 V. Meanwhile, when the trench interval in the diode portion 80 is 12 μm or more, the breakdown voltage of the diode portion 80 can be made smaller than 1425 V. The trench length of the diode portion 80 may be 2.4 times or more, may be 3 times or more, or may be 5 times or more the trench length of the transistor portion 70.

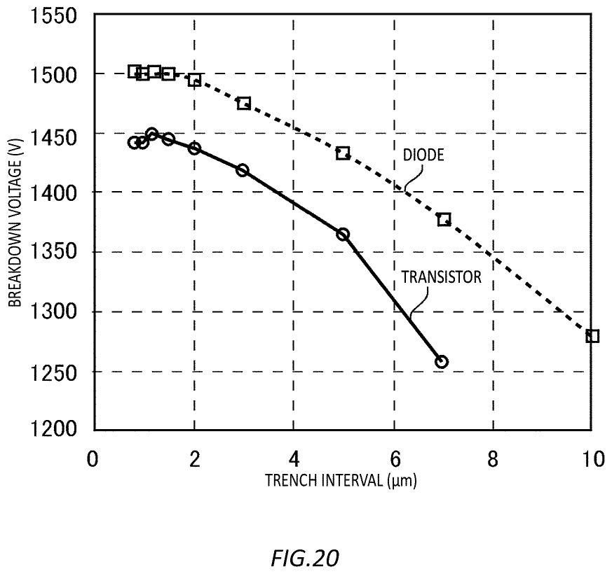

FIG. 20 illustrates the relationship between the trench interval in the transistor portion 70 and the diode portion 80 and the avalanche breakdown voltage in the transistor portion 70 and the diode portion 80. The diode portion 80 of this example is the same as the diode portion 80 of the example of FIG. 18. The transistor portion 70 of the example of FIG. 18 is not provided with the first lower end region 202, but the transistor portion 70 of this example is provided with the first lower end region 202. The transistor portion 70 of this example is the same as the transistor portion 70 of the example of FIG. 18 except that the first lower end region 202 is provided. As illustrated in FIGS. 18 and 20, the first lower end region 202 is provided so that the avalanche breakdown voltage of the transistor portion 70 rises. That is, the avalanche breakdown voltage can be adjusted by providing the first lower end region 202.

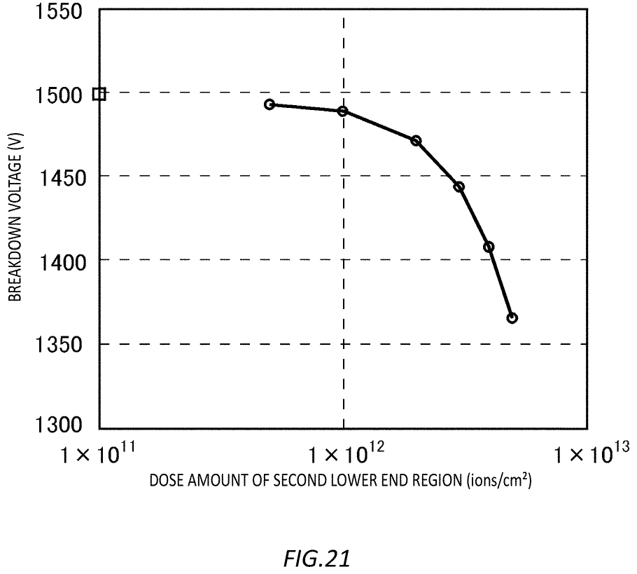

FIG. 21 illustrates a relationship between a dose amount (or doping concentration) in the second lower end region 204 in the diode portion 80 and the avalanche breakdown voltage in the diode portion 80. In FIG. 21, the avalanche breakdown voltage when the second lower end region 204 is not provided is indicated by a square plot. When the dose amount of the second lower end region 204 is increased, the avalanche breakdown voltage decreases. That is, the avalanche breakdown voltage can be adjusted by adjusting the dose amount of the second lower end region 204.

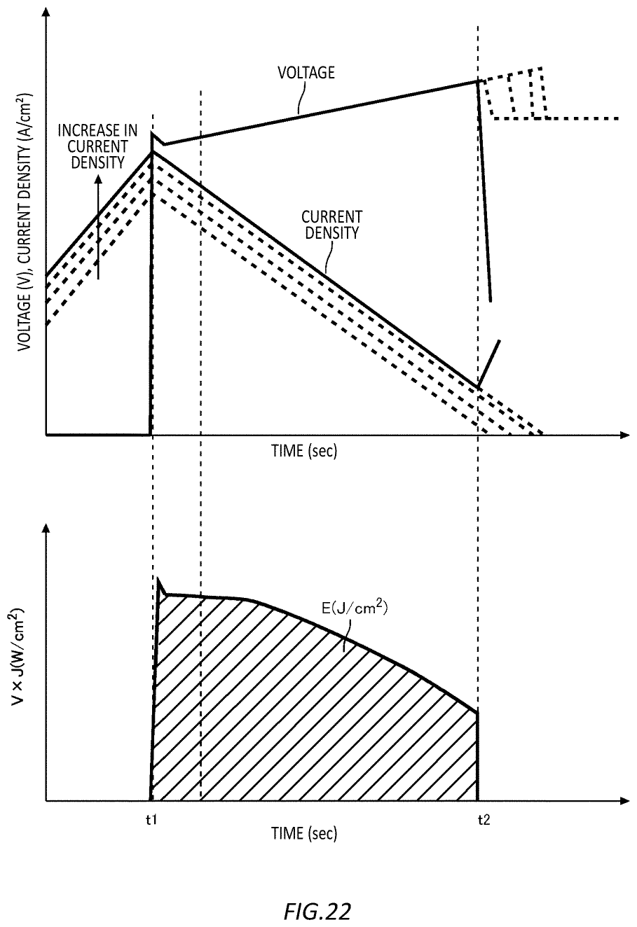

FIG. 22 illustrates a non-destructive maximum energy density of the semiconductor device 100. The non-destructive maximum energy density refers to an energy density which, when the energy applied to the semiconductor device 100 is gradually increased in an unclamped inductive switching test (UIS test), is applied immediately until the semiconductor device 100 is broken down.

When the semiconductor device 100 is transitioned from an on state to an off state at time t1, the current density of the main current flowing through the semiconductor device 100 gradually decreases, and the collector-emitter voltage of the semiconductor device 100 rises. The energy obtained by time-integrating the product (V×J) of the main current density and the collector-emitter voltage as illustrated in the graph on the lower side of FIG. 22 is applied to the semiconductor device 100.

When the current density of the main current flowing when the semiconductor device 100 is in the on state is sequentially raised and a turn-off operation is repeated, the semiconductor device 100 is broken down at time t2 in the turn-off operation at a certain current density, and the main current rapidly increases. The energy slightly smaller than the energy applied from the time t1 to the time t2 in the turn-off operation is the non-destructive maximum energy density. The applied energy in the turn-off operation may be set as the non-destructive maximum energy density, the non-destructive maximum energy density may be set by subtracting a predetermined margin from the applied energy in the turn-off operation, or the applied energy in the turn-off operation immediately before the turn-off operation may be set as the non-destructive maximum energy density.

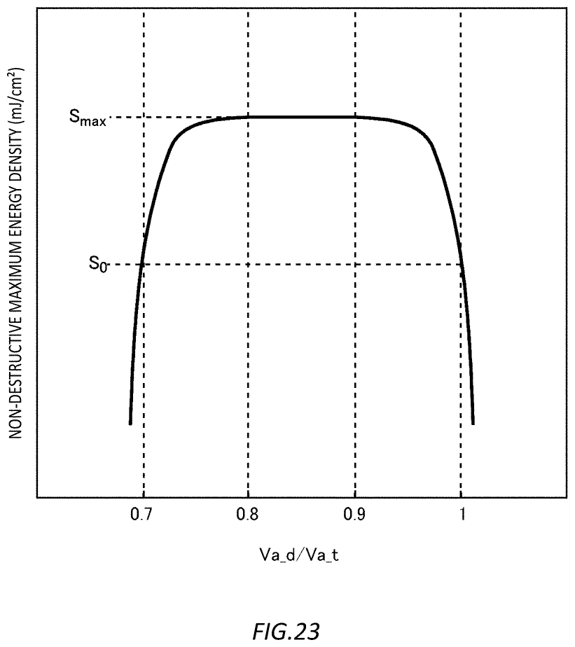

FIG. 23 illustrates a relationship between the avalanche breakdown voltage Va_d in the diode portion 80 and the non-destructive maximum energy density. A horizontal axis in FIG. 23 represents the avalanche breakdown voltage Va_d normalized by the avalanche breakdown voltage Va_t in the transistor portion 70 (that is, Va_d/Va_t).

The non-destructive maximum energy density when the avalanche breakdown voltage Va_d in the diode portion 80 is the same as the avalanche breakdown voltage Va_t in the transistor portion 70 (Va_d/Va_t=1) is defined as a reference value S.

The semiconductor device 100 may have an avalanche breakdown voltage ratio of the diode portion 80 and the transistor portion 70 such that the non-destructive maximum energy density is larger than the reference value S₀. As an example, in the semiconductor device 100, the avalanche breakdown voltage Va_d of the diode portion 80 is 70% or more and less than 100% of the avalanche breakdown voltage Va_t of the transistor portion 70.

The semiconductor device 100 may have an avalanche breakdown voltage ratio of the diode portion 80 and the transistor portion 70 such that the non-destructive maximum energy density is 80% or more of a maximum value Sₘₐₓ. The semiconductor device 100 may have an avalanche breakdown voltage ratio of the diode portion 80 and the transistor portion 70 such that the non-destructive maximum energy density is 90% or more of the maximum value Sₘₐₓ. The semiconductor device 100 may have an avalanche breakdown voltage ratio of the diode portion 80 and the transistor portion 70 such that the non-destructive maximum energy density is equal to or more than an intermediate value between the reference value S and the maximum value Sₘₐₓ. In the semiconductor device 100, the avalanche breakdown voltage Va_d of the diode portion 80 may be 75% or more, or may be 80% or more of the avalanche breakdown voltage Va_t of the transistor portion 70. In the semiconductor device 100, the avalanche breakdown voltage Va_d of the diode portion 80 may be less than 100%, may be 95% or less, or may be 90% or less of the avalanche breakdown voltage Va_t of the transistor portion 70.

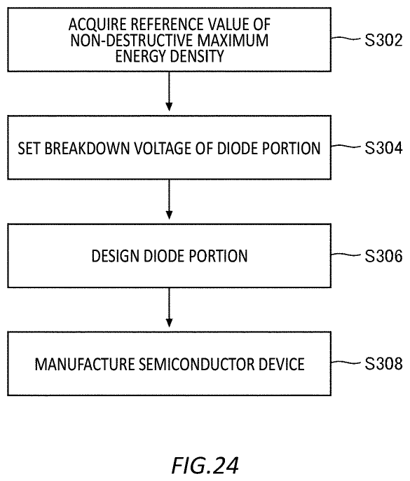

FIG. 24 illustrates an example of a manufacturing method of the semiconductor device 100. First, in a reference value acquisition step S302, the reference value S of the non-destructive maximum energy density described in FIGS. 22 and 23 is acquired using one or more semiconductor devices. In S302, the reference value S₀ is acquired by the unclamped inductive switching test. One or more semiconductor devices used to acquire the reference value S₀ are referred to as first semiconductor devices.

Next, in a setting step S304, as described with reference to FIG. 23, the avalanche breakdown voltage ratio of the diode portion 80 and the transistor portion 70 is set such that the non-destructive maximum energy density is larger than the reference value S₀.

Next, in a design step S306, the structures of the diode portion 80 and the transistor portion 70 are designed so as to satisfy the avalanche breakdown voltage ratio set in S304. In S306, as described in FIGS. 5 to 17, the avalanche breakdown voltage ratio of the diode portion 80 and the transistor portion 70 is adjusted by adjusting the interval of the trench portions, the depth of the trench portion, the arrangement of the first lower end region 202, the arrangement of the second lower end region 204, the arrangement of the lifetime adjustment portion 208, or the like. The semiconductor device in which the avalanche breakdown voltage ratio of the diode portion 80 and the transistor portion 70 are adjusted is referred to as a second semiconductor device.

Next, in a manufacturing step S308, the semiconductor device 100 is manufactured on the basis of the design of S306. The semiconductor device 100 is the second semiconductor device. Accordingly, the semiconductor device 100 can be manufactured. The semiconductor device 100 has the avalanche breakdown voltage described in FIG. 5.

While the present invention has been described by way of the embodiments, the technical scope of the present invention is not limited to the above described embodiments. It is apparent to persons skilled in the art that various alterations or improvements can be made to the above described embodiments. It is apparent from the description of the claims that embodiments added with such alterations or improvements can also be included in the technical scope of the present invention.

Note that the operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

What is claimed is:

1. A semiconductor device comprising:
a semiconductor substrate which has an upper surface and a lower surface and is provided with a drift region of a first conductivity type;
a transistor portion which includes a collector region of a second conductivity type in contact with the lower surface of the semiconductor substrate and an emitter region of the first conductivity type provided in contact with the upper surface of the semiconductor substrate and having a doping concentration higher than that of the drift region; and
a diode portion which includes a cathode region of the first conductivity type in contact with the lower surface of the semiconductor substrate, wherein
an avalanche breakdown voltage in the diode portion is 0.7 times or more and less than 1 time an avalanche breakdown voltage in the transistor portion.

2. The semiconductor device according to claim 1, wherein
a cathode voltage at which the diode portion reaches a negative resistance region is equal to or larger than a collector voltage at which the transistor portion reaches a negative resistance region.

3. The semiconductor device according to claim 1, wherein
the diode portion and the transistor portion include a plurality of trench portions, which are arranged at intervals along an array direction, on the upper surface of the semiconductor substrate.

4. The semiconductor device according to claim 3, wherein
at least some of the trench portions in the transistor portion are arranged at a first interval in the array direction, and
at least some of the trench portions in the diode portion are arranged at a second interval larger than the first interval in the array direction.

5. The semiconductor device according to claim 4, comprising
an intermediate region which is arranged between the diode portion and the transistor portion, is provided with a plurality of the trench portions, and includes at least one of the cathode region or the collector region, wherein
the intermediate region includes a transistor side region, the transistor side region is in contact with the transistor portions, and one or more of the trench portions are arranged at the first interval.

6. The semiconductor device according to claim 4, comprising
an intermediate region which is arranged between the diode portion and the transistor portion, is provided with a plurality of the trench portions, and includes at least one of the cathode region or the collector region, wherein
the intermediate region includes a transistor side region, the transistor side region is in contact with the transistor portions, and one or more of the trench portions are arranged at an interval smaller than the first interval.

7. The semiconductor device according to claim 5, wherein
a boundary position between the cathode region and the collector region in the intermediate region is arranged in the transistor side region.

8. The semiconductor device according to claim 7, wherein
the boundary position is arranged below the trench portion, which is closest to the diode portion, among one or more of the trench portions in the transistor side region.

9. The semiconductor device according to claim 7, wherein
the transistor side region includes a first trench portion, identical to the trench portion, and a second trench portion, identical to the trench portion, between which an interval in the array direction is smallest in the intermediate region, and
the boundary position is arranged in a region from below the first trench portion to below the second trench portion.

10. The semiconductor device according to claim 5, wherein
an interval in the array direction of the plurality of trench portions in the intermediate region increases when approaching the diode portion.

11. The semiconductor device according to claim 4, wherein
the second interval is 2 times or more the first interval.

12. The semiconductor device according to claim 3, wherein
at least some of the trench portions in the transistor portion have a first length in a depth direction of the semiconductor substrate, and
at least some of the trench portions in the diode portion have a second length larger than the first length in the depth direction.

13. The semiconductor device according to claim 12, comprising
an intermediate region which is arranged between the diode portion and the transistor portion, is provided with a plurality of the trench portions, and includes the cathode region and the collector region, wherein
the intermediate region includes a transistor side region in contact with the transistor portion, and
the transistor side region includes the trench portion having the first length.

14. The semiconductor device according to claim 12, comprising
an intermediate region which is arranged between the diode portion and the transistor portion, is provided with a plurality of the trench portions, and includes the cathode region and the collector region, wherein
the intermediate region includes a transistor side region in contact with the transistor portion, and
the transistor side region includes the trench portion having a length smaller than the first length.

15. The semiconductor device according to claim 13, wherein
a boundary position between the cathode region and the collector region in the intermediate region is arranged in the transistor side region.

16. The semiconductor device according to claim 13, wherein
a length in the depth direction of the plurality of trench portions in the intermediate region increases when approaching the diode portion.

17. The semiconductor device according to claim 3, wherein
the transistor portion includes a first lower end region of the second conductivity type provided in contact with a lower end of at least one of the trench portions, and
a lower end of at least one of the trench portions of the diode portion is not in contact with a region of the second conductivity type.

18. The semiconductor device according to claim 17, wherein
lower ends of all of the trench portions of the diode portion are not in contact with the region of the second conductivity type.

19. The semiconductor device according to claim 3, wherein
the diode portion includes a second lower end region of the first conductivity type provided in contact with a lower end of at least one of the trench portions and having a doping concentration higher than that of the drift region, and
a lower end of at least one of the trench portions of the transistor portion is not in contact with a region of the first conductivity type having a doping concentration higher than that of the drift region.

20. The semiconductor device according to claim 19, wherein
the transistor portion includes:
a base region of the second conductivity type provided between the emitter region and the drift region; and
an accumulation region of the first conductivity type provided between the base region and the drift region and having a doping concentration higher than that of the drift region, and
a doping concentration of the second lower end region is lower than a doping concentration of the accumulation region.

21. The semiconductor device according to claim 1, wherein
the diode portion includes a lifetime adjustment portion, which adjusts a lifetime of a carrier, on the upper surface side of the semiconductor substrate.

22. A semiconductor device comprising:
a semiconductor substrate which has an upper surface and a lower surface and is provided with a drift region of a first conductivity type;
a transistor portion which includes a collector region of a second conductivity type in contact with the lower surface of the semiconductor substrate and an emitter region of the first conductivity type provided in contact with the upper surface of the semiconductor substrate and having a doping concentration higher than that of the drift region; and
a diode portion which includes a cathode region of the first conductivity type in contact with the lower surface of the semiconductor substrate, wherein
the diode portion and the transistor portion include a plurality of trench portions, which are arranged at intervals along an array direction, on the upper surface of the semiconductor substrate,
the transistor portion includes a first lower end region of the second conductivity type provided in contact with a lower end of at least one of the trench portions, and
a lower end of at least one of the trench portions of the diode portion is not in contact with a region of the second conductivity type.

23. A manufacturing method of a semiconductor device including a transistor portion and a diode portion on a semiconductor substrate, the manufacturing method comprising:
acquiring, for a first semiconductor device in which breakdown voltages of the transistor portion and the diode portion are equal, a non-destructive maximum energy density at which the semiconductor device is not broken down, by an unclamped inductive switching test;
setting an avalanche breakdown voltage ratio of the diode portion and the transistor portion with reference to the first semiconductor device such that the non-destructive maximum energy density is larger than that of the first semiconductor device;
designing the transistor portion and the diode portion in a second semiconductor device so as to satisfy the avalanche breakdown voltage ratio being set; and
manufacturing the second semiconductor device on a basis of the designing.

24. The semiconductor device according to claim 3, comprising:
an intermediate region which is arranged between the diode portion and the transistor portion, is provided with a plurality of the trench portions, and includes at least one of the cathode region or the collector region, wherein
an avalanche breakdown voltage of the intermediate region is larger than an avalanche breakdown voltage of the diode portion and smaller than an avalanche breakdown voltage of the transistor portion.

25. The semiconductor device according to claim 12, comprising:
an intermediate region which is arranged between the diode portion and the transistor portion, is provided with a plurality of the trench portions, and includes the cathode region and the collector region, wherein
the intermediate region includes a transistor side region in contact with the transistor portion, and
the transistor side region includes the trench portion having a length larger than the first length.

26. The semiconductor device according to claim 1, wherein
a cathode voltage at which the diode portion reaches a negative resistance region is smaller than a collector voltage at which the transistor portion reaches a negative resistance region.

27. The semiconductor device according to claim 1, wherein
an avalanche breakdown voltage in the diode portion is 0.75 times or more and 0.95 times or less an avalanche breakdown voltage in the transistor portion.
